(19) United States
(12) Patent Application Publication
(10) Pub. No.: US 2007/0274433 A1
(43) Pub. Date: Nov. 29, 2007

(54) SHIFT REGISTER CIRCUIT AND IMAGE DISPLAY APPARATUS EQUIPPED WITH THE SAME

(75) Inventor: Youichi Tobita, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Tokyo (JP)

(21) Appl. No.: 11/741,232

(22) Filed: Apr. 27, 2007

(30) Foreign Application Priority Data
May 25, 2006 (JP) 2006-144872

(51) Int. Cl. G11C 19/00

(52) U.S. Cl. 377/64

(57) ABSTRACT

Malfunction caused by leakage current of the transistor and shift in threshold voltage is prevented in the shift register in which the signal can be shifted bi-directionally. The bi-directional unit shift register includes a first transistor Q1 for providing a first clock signal CLK to an output terminal OUT, a second transistor Q2 for discharging the output terminal OUT based on a second clock signal, third and fourth transistors Q3, Q4 for providing first and second voltage signals Vn, Vr complementary to each other to a first node, which is a gate node of the first transistor Q1, and a fifth transistor Q5 connected between the first node and the output terminal OUT. The fifth transistor Q5 is in an electrically conducted state based on the first clock signal CLK when the gate of the transistor Q1 is at L (Low) level.

### BACKGROUND OF THE INVENTION

1. Field of the Invention

The present invention relates to shift register circuits configured only by field effect transistors of the same conductivity type used in scanning line driving circuit and the like of the image display apparatus etc., in particular, to a bi-directional shift register in which the direction of shifting the signal can be reversed.

2. Description of the Background Art

In the image display apparatus (hereinafter referred to as “display apparatus”), such as a liquid crystal display apparatus, a gate line (scanning line) is arranged for each pixel row (pixel line) of a display panel in which a plurality of pixels are arrayed in a matrix form, and the gate line is sequentially selected and driven at a cycle of one horizontal period of the display signal to update the displayed image. A shift register for performing the shift operation that completes the round in one frame period of the display signal is used for the gate line driving circuit (scanning line driving circuit) to sequentially select and drive the pixel line, that is, the gate line.

The shift register used in the gate line driving circuit is desirably configured only by the field effect transistors of the same conductivity type in order to reduce the number of steps in the manufacturing process of the display apparatus. Various shift registers configured only by the field effect transistors of N-type or P-type and display apparatuses mounted with the same are proposed. MOS (Metal Oxide Semiconductor) transistor and TFT (Thin Film Transistor) etc. are used as the field effect transistor.

The gate line driving circuit is configured by the shift register comprising a plurality of stages. That is, the gate line driving circuit is configured by cascade connecting a plurality of shift register circuits arranged for every pixel line, that is, every gate line. In the present specification, each of the plurality of shift register circuits configuring the gate line driving circuit is referred to as “unit shift register” for the sake of convenience of the explanation.

In a liquid crystal display apparatus of matrix type in which the liquid crystal pixels are arranged in a matrix form, for example, the request to change the display pattern such as inverting the displayed image upside down or mirror reversing the same and changing the displaying order when displaying is often made.

The display inversion is desired, for example, when applying the liquid crystal display apparatus to an OHP (Overhead Projector) projection apparatus, and using a translucent screen. This is because, when the translucent screen is used, the picture on the screen is inverted as opposed to when projecting the picture from the front side of the screen since the picture is projected from the back side of the screen when seen from the viewer. The change in displaying order is desired when rendition effect is desired in displaying a bar graph, histogram etc. such as gradually appearing the displaying image from the top to the bottom or vice versa, that is, gradually appearing from the bottom to the top.

One method of performing display pattern change of such display apparatus includes switching the shift direction of the signal in the gate line driving circuit. The shift register (hereinafter referred to as “bi-directional shift register”) in which the shift direction of the signal can be switched is thus proposed.

For example, the unit shift register (hereinafter also referred to as “bi-directional unit shift register”) used in the bi-directional shift register configured only by the field effect transistors of N-channel type is disclosed in FIG. 13 of Japanese Patent Application Laid-Open No. 2001-350438 below (similar circuit is shown in FIG. 3 of the present specification, where the reference number in parentheses below correspond to those in FIG. 3).

The output stage of the unit shift register is configured by a first transistor (Q1) for providing a clock signal (CLK) input to a clock terminal (CK) to an output terminal (OUT), and a second transistor (Q2) for supplying a reference voltage (VSS) to the output terminal. A gate node (N1) of the first transistor is defined as the first node, and a gate node (N2) of the second transistor is defined as the second node.

The unit shift register includes a third transistor (Q3) for providing a first voltage signal (Vn) to the first node based on the signal input to a predetermined first input terminal (IN1), and a fourth transistor (Q4) for providing a second voltage signal (Vr) to the first node based on the signal input to a predetermined second input terminal (IN2). The first and second voltage signals are signals complementary to each other where when one of the voltage level (hereinafter referred to simply as “level”) is H (High), the other voltage level is L (Low) level.

The first transistor is driven by the third and fourth transistors. The second transistor is driven by an inverter (Q6, Q7) having the first node as an input end and a second node as an output end. In other words, when the relevant unit shift register outputs the output signal, the first node is at H level due to the operation of the second and third transistors, and the second node is accordingly at L level due to the inverter. The first transistor is thereby turned ON, the second transistor is turned OFF, and the clock signal is transmitted to the output terminal in such state, whereby the output signal is output. If the output signal is not output, on the other hand, the first node is at L level due to the operation of the second and third transistors, and the second node is accordingly at H level due to the inverter. The first transistor is thereby turned OFF, the second transistor is turned ON, and the voltage level of the output terminal is maintained at L level.

If the first voltage signal is at H level and the second voltage signal is at L level, for example, the first node becomes H level and the second node accordingly becomes L level when the signal is input to the first input terminal, whereby the first transistor is turned ON and the second transistor is turned OFF. Therefore, the output signal is output from the relevant unit shift register at a timing the clock signal is subsequently input. In other words, when the first voltage signal is at H level and the second voltage signal is at L level, the relevant unit shift register operates to output the signal input to the first input terminal in a temporally shifted manner.

On the other hand, if the first voltage signal is at L level and the second voltage signal is at H level, the first node becomes H level and the second node accordingly becomes L level when the signal is input to the second input terminal, whereby the first transistor is turned ON and the second transistor is turned OFF. Therefore, the output signal is output from the relevant unit shift register at a timing the clock signal is subsequently input. In other words, when the first voltage signal is at L level and the second voltage signal is at H level, the relevant unit shift register operates to output the signal input to the second input terminal in a temporally shifted manner.

The bi-directional unit shift register of FIG. 13 of Japanese Patent Application Laid-Open No. 2001-350438 (FIG. 3 of the present specification) switches the shift direction of the signal by switching the levels of the first voltage signal and the second voltage signal for driving the first transistor.

A first problem of the conventional bi-directional shift register will be described first. When configuring the gate line driving circuit by cascade connecting the conventional bi-directional unit shift registers, the output signal of the previous stage is input to the first input terminal (IN1) of the unit shift register of each stage, and the output signal of the next stage is input to the second input terminal (IN2) (see FIG. 2 of the present specification). The output signal (gate line driving signal) is output only during one specific horizontal period within one frame period from the respective unit shift register, and is not output during other periods since the gate line driving circuit operates to sequentially select each gate line at a cycle of one frame period. Therefore, the third and fourth transistors (Q3, Q4) driving the first transistor (Q1) are turned OFF most of the time during one frame period in each unit shift register.

In the conventional unit shift register, the gate of the first transistor, that is, the first node (N1) is in the floating state when the third and fourth transistors are turned OFF. In particular, the period (non-selective period) in which the output signal is not output continues for a length of about one frame period, during which period, the first node is maintained at L level of floating state, and the first transistor is maintained in the OFF state. If leakage current is generated in the third transistor (when first voltage signal is at H level) or the fourth transistor (when second voltage signal is at H level), the charges involved therewith accumulates at the first node in the floating state, and the potential of the first node gradually rises.

Furthermore, the clock signal is continuously input to the clock terminal (CK) (drain of first transistor) even during the non-selective period, and the potential of the first node rises while the clock signal is at H level due to coupling via overlapping capacity between drain and gate of the first transistor. In the description of the present specification, each transistor is assumed to be an N-type transistor, and thus the transistors are activated (turned ON) at H level of the clock signal, and inactivated (turned OFF) at L level. The states of the transistor become the opposite in the case of the P-type transistor.

When the potential of the first node rises by the leakage current and the clock signal, the problem of malfunction arises in which the first transistor that is to be turned OFF is turned ON, and the gate line is unnecessarily activated when the voltage between the gate and the source of the first transistor exceeds a threshold voltage. When a pixel switch element (active transistor) arranged on each pixel is turned ON, the data in the pixel is re-written, and display defect occurs.

Next, a second problem will be described. The first node (N1) is at H level of the floating state and the first transistor (Q1) is maintained in the ON state during the period (selective period) the bi-directional unit shift register outputs the output signal. When the clock signal of the clock terminal (CK) (drain of first transistor) becomes H level, the output terminal (OUT) becomes H level following thereto, and the gate line is activated. In this case, the first node is boosted while the clock signal is at H level due to coupling via the drain-gate overlapping capacity, the gate-channel capacity, and the gate-source overlapping capacity of the first transistor. The boost of the first node increases the driving ability (ability to flow current) of the first transistor, whereby the relevant unit shift register charges the gate line at high speed.

However, when the first node is boosted, high voltage is applied between the drain and the source of the third transistor (Q3) (when first voltage signal is at L level) or the fourth transistor (Q4) (when second voltage is at L level), and thus the leakage current tends to be easily generated depending on the voltage resistance property of between the drain and the source. When the level of the first node lowers due to the leakage current, the driving ability of the first transistor lowers, and the falling speed of the output signal of when the clock signal returns from H level to L level becomes slower. If the turning OFF of the pixel transistor is delayed, the data in the pixel may be re-written on the data of the next line, and display failure may occur.

A third problem will be described. In the gate line driving circuit configured by the conventional bi-directional shift register, a control pulse referred as “start pulse” corresponding to the head of each frame of the image signal is input as input signal to the first input terminal (IN1) of the unit shift register of the leading stage in the case of forward shift of shifting the signal in the direction of the previous stage to the subsequent stage and the like. The input signal is sequentially transmitted to each cascade connected unit shift register to the unit shift register of the final stage. In the conventional bi-directional shift register, a control pulse referred to as “end pulse” corresponding to the end of each frame period of the image signal must be input to the second input terminal (IN2) of the final stage immediately after the unit shift register of the final stage outputs the output signal. Otherwise, the first transistor of the final stage cannot be turned OFF, and the output signal continues to be output from the final stage.

In the case of a normal shift register for shifting the signal only in one direction, the end pulse is less likely to become necessary and is sufficiently with the start pulse since a dummy stage is further arranged in the next stage after the final stage and the output signal thereof is used as the end pulse, or the clock signal having a phase different from the clock signal input to the final stage is used as the end pulse. Therefore, most of the drive controlling devices for controlling the operation of the normal gate line driving circuit for shifting the signal (gate line driving signal) only in one direction output only the start pulse.

In the case of the bi-directional shift register, however, the start pulse must be input in the reverse shift to shift the signal in the direction of subsequent stage to previous stage in addition to inputting the end pulse to the second input terminal of the final stage. Furthermore, it is not as simple as with shifting in only one direction since the output signal of the dummy stage may become the wrong start pulse when the shift direction is reversed, if the dummy stage is simply arranged. Therefore, the drive controlling device of the gate line driving circuit for shifting the signal in bi-direction mounted with the output circuit of not only the start pulse but also of the end pulse is adopted, which increases the cost of the drive controlling device, that is, increases the cost of the display apparatus.

The fourth problem will be described. The display apparatus in which the unit shift register of the gate line driving circuit is configured by amorphous silicon TFT (a-Si TFT) is recently widely being used, but the a-Si TFT has a drawback in that the threshold voltage shifts and the driving ability (ability to flow current) lowers when the gate electrode is continuously biased to positive. Similar problem is found not only in a-Si TFT, but also in an organic TFT.

In each unit shift register configuring the gate line driving circuit, the period (non-selective period) the output signal is not output continues for a length of about one frame period. In the conventional unit shift register, the second node (N2) is maintained at H level to turn ON the second transistor and maintain the output terminal (OUT) at L level during the relevant period. That is, the gate of the second transistor is continuously biased to positive, and if occurred in a-Si TFT, organic TFT and the like, the driving ability gradually lowers. When such phenomenon advances, the output terminal becomes a floating state in the non-selective period, and the potential of each gate line becomes unstable, whereby malfunction is likely to occur, and the display quality degrades.

### SUMMARY OF THE INVENTION

First object of the present invention is to suppress malfunction caused by leakage current of the constituting transistor and shift in threshold voltage in a bi-directional unit shift register. Second object of the present invention is to provide a bi-directional shift register in which input of an end pulse is not necessary.

A shift register circuit of the present invention includes, first and second input terminals, an output terminal and a clock terminal; and first and second voltage signal terminals and first to fourth transistors. The first and second voltage signal terminals are input with first and second voltage signals complementary to each other. The first transistor provides a first clock signal input to the first clock terminal to the output terminal. The second transistor discharges the output terminal based on a second clock signal having a phase different from the first clock signal. The third transistor provides the first voltage signal to a first node connected with a control electrode of the first transistor based on a first input signal input to the first input terminal. The fourth transistor provides the second voltage signal to the first node based on a second input signal input to the second input terminal. The shift register circuit includes a switching circuit for electrically conducting the first node and the output terminal based on the first clock signal when the first node is discharged.

The control electrode of the first transistor is sufficiently boosted since the current does not flow to the switching circuit in time of output of the output signal (first clock signal transmitted to the output terminal via the first transistor), and the driving ability of the first transistor is widely ensured. The rise and fall speed of the output signal can be increased, thereby contributing to higher speed of the operation. Since the switching circuit is turned ON in the period (non-selective period) in which the output signal is not output, the control electrode of the first transistor is discharged and L level is maintained. The first transistor is thereby turned ON in the non-selective period, thereby preventing the output signal from unnecessarily becoming H level. That is, advantages of preventing malfunction in the non-selective period, and preventing lowering of the driving ability in time of output of the output signal are obtained.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic block diagram showing a configuration of a display apparatus according to an embodiment of the present invention;

FIG. 2 is a block diagram showing a configuration example of a gate line driving circuit using a conventional bi-directional unit shift register;

FIG. 3 is a circuit diagram of the conventional bi-directional unit shift register:

FIG. 4 is a timing chart showing the operation of the gate line driving circuit;

FIG. 5 is a block diagram showing a configuration example of a gate line driving circuit using a bi-directional unit shift register;

FIG. 6 is a block diagram showing a configuration example of a gate line driving circuit using a conventional bi-directional unit shift register;

FIG. 7 is a block diagram showing a configuration of a gate line driving circuit according to a first embodiment;

FIG. 8 is a circuit diagram showing a configuration of the bi-directional unit shift register according to the first embodiment;

FIG. 9 is a timing chart showing the operation of the bi-directional unit shift register according to the first embodiment;

FIG. 10 is a view explaining the operation of the bi-directional unit shift register according to the first embodiment;

FIG. 11 is a timing chart showing the operation of the bi-directional unit shift register according to the first embodiment;

FIG. 12 is a block diagram showing a variant of the gate line driving circuit according to the first embodiment;

FIG. 13 is a circuit diagram showing a configuration of the bi-directional unit shift register according to a second embodiment;

FIG. 14 is a circuit diagram showing a configuration of the bi-directional unit shift register according to a third embodiment;

FIG. 15 is a circuit diagram showing a variant of a level adjustment circuit in a fourth embodiment;

FIG. 16 is a circuit diagram showing a variant of a level adjustment circuit in the fourth embodiment;

FIG. 17 is a circuit diagram showing a variant of a level adjustment circuit in the fourth embodiment;

FIG. 18 is a circuit diagram showing a variant of a level adjustment circuit in the fourth embodiment;

FIG. 19 is a circuit diagram showing a variant of a level adjustment circuit in the fourth embodiment;

FIG. 20 is a circuit diagram of a bi-directional unit shift register according to a fifth embodiment;

FIG. 21 is a timing chart showing the operation of the bi-directional unit shift register according to the fifth embodiment;

FIG. 22 is a circuit diagram of a bi-directional unit shift register according to a sixth embodiment;

FIG. 23 is a timing chart showing the operation of the bi-directional unit shift register according to the sixth embodiment;

FIG. 24 is a circuit diagram of a bi-directional unit shift register according to a seventh embodiment;

FIG. 25 is a circuit diagram of a bi-directional unit shift register according to an eighth embodiment;

FIG. 26 is a circuit diagram of a bi-directional unit shift register according to a ninth embodiment;

FIG. 27 is a circuit diagram of a bi-directional unit shift register according to a tenth embodiment;

FIG. 28 is a block diagram showing a configuration example of a gate line driving circuit using a bi-directional unit shift register according to an eleventh embodiment;

FIG. 29 is a circuit diagram showing a configuration example of the gate line driving circuit according to the eleventh embodiment;

FIG. 30 is a circuit diagram showing a configuration example of the gate line driving circuit according to the eleventh embodiment;

FIG. 31 is a timing chart showing the operation of the gate line driving circuit according to the eleventh embodiment;

FIG. 32 is a timing chart showing the operation of the gate line driving circuit according to the eleventh embodiment;

FIG. 33 is a circuit diagram showing a configuration example of the gate line driving circuit according to the eleventh embodiment; and

FIG. 34 is a circuit diagram showing a configuration example of the gate line driving circuit according to the eleventh embodiment.

### DESCRIPTION OF THE PREFERRED EMBODIMENTS

The embodiments of the present invention will now be described with reference to the drawings. The same reference characters are denoted for elements having same or corresponding functions throughout the drawings to avoid redundant explanation.

### First Embodiment

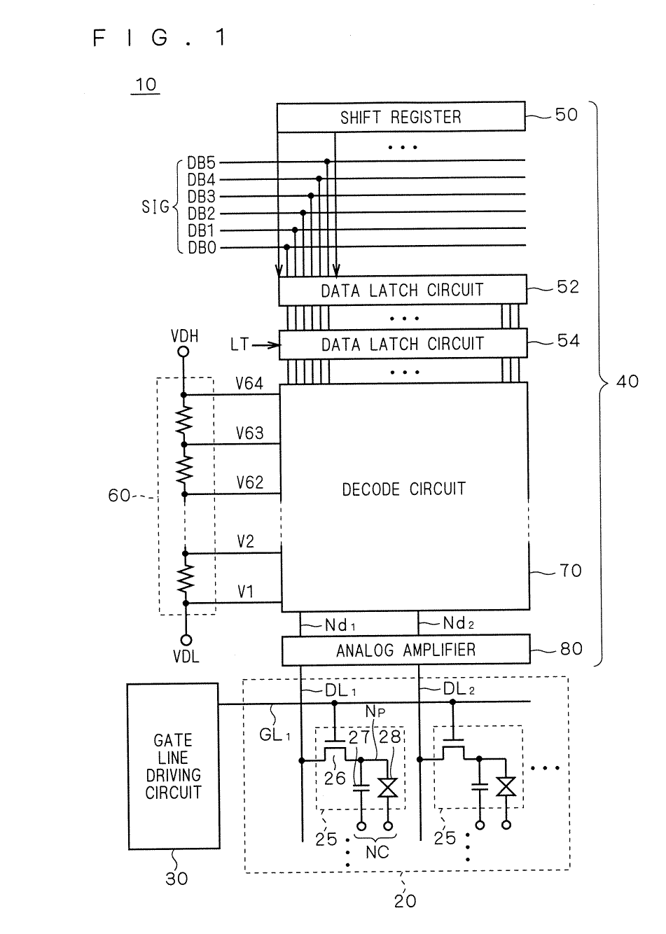

FIG. 1 is a schematic block diagram showing the configuration of a display apparatus according to a first embodiment of the present invention, showing the entire configuration of a liquid crystal display apparatus 10 as one example of the display apparatus.

The liquid crystal display apparatus 10 includes a liquid crystal array section 20, a gate line driving circuit (scanning line driving circuit) 30, and a source driver 40. As to be apparent from the description below, the bi-directional shift register according to the embodiment of the present invention is mounted on the gate line driving circuit 30, and is integrally formed with the liquid crystal array section 20.

The liquid crystal array section 20 includes a plurality of pixels 25 arranged in a matrix form. The gate lines GL₁, GL₂, . . . (collectively referred to as “gate line GL”) are arranged on each row of pixels (hereinafter referred to also as “pixel line”), and the data lines DL₁, DL₂, . . . (collectively referred to as “data line DL”) are arranged on each column of pixels (hereinafter referred to also as “pixel column”). FIG. 1 shows the pixels 25 in first and second columns on the first row, and the gate line GL₁ as well as the data lines DL₁, DL₂ corresponding thereto by way of example.

Each pixel 25 includes a pixel switch element 26 arranged between the corresponding data line DL and the pixel node Np, and a capacitor 27 and a liquid crystal display element 28 connected in parallel between the pixel node Np and a common electrode node NC. The orientation of the liquid crystals in the liquid crystal display element 28 changes according to the voltage difference between the pixel node Np and the common electrode node NC, and the display luminance of the liquid crystal display element 28 changes in response thereto. Thus, the luminance of each pixel can be controlled by the display voltage transmitted to the pixel node Np via the data line DL and the pixel switch element 26. In other words, the intermediate luminance can be obtained by applying the intermediate voltage difference between the voltage difference corresponding to the maximum luminance and the voltage difference corresponding to the minimum luminance to between the pixel node Np and the common electrode node NC. Therefore, the tone-wise luminance can be obtained by setting the display voltage in a step-wise manner.

The gate line driving circuit 30 selects and drives the gate line GL in order based on a predetermined scanning period. In the present embodiment, the gate line driving circuit 30 is configured by a bi-directional shift register in which the direction of the order of activating the gate line GL can be switched. The gate electrodes of the pixel switch element 26 are connected to the corresponding gate lines GL. While a specific gate line GL is being selected, the pixel switch element 26 is in the electrically conducting state at each pixel connected to the relevant gate line, and the pixel node Np is connected to the corresponding data line DL. The display voltage transmitted to the pixel node Np is held by the capacitor 27. Generally, the pixel switch element 26 is configured by the TFT formed on the same insulation substrate (glass substrate, resin substrate etc.) as the liquid crystal display element 28.

The source driver 40 is provided to output the display voltage set in a step-wise manner by the display signal SIG, which is the digital signal of N bits, to the data line DL. The display signal SIG is a signal of 6 bits, and is configured by display signal bits DB0 to DB5, by way of example. 2⁶=64 steps of tone display is possible in each pixel based on the display signal SIG of 6 bits. Furthermore, if one color display unit is formed by three pixels of R (Red), G (Green) and B (Blue), color display of about 260 thousand colors becomes possible.

As shown in FIG. 1, the source driver 40 includes a shift register 50, data latch circuits 52, 54, a tone voltage generation circuit 60, a decode circuit 70, and an analog amplifier 80.

The display signal bits DB0 to DB5 corresponding to the display luminance of each pixel 25 are serially generated in the display signal SIG. That is, the display signal bits DB0 to DB5 at each timing indicate the display luminance at one of the pixels 25 in the liquid crystal array section 20.

The shift register 50 instructs the retrieval of the display signal bits DB0 to DB5 to the data latch circuit 52 at a timing synchronized with the period the setting of the display signal SIG is switched. The data latch circuit 52 retrieves the serially generated display signal SIG one by one, and holds the display signal SIG worth of one pixel line.

A latch signal LT input to the data latch circuit 54 is activated at a timing the display signal SIG worth of one pixel line is retrieved by the data latch circuit 52. In response thereto, the data latch circuit 54 retrieves the display signal SIG worth of one pixel line held in the data latch circuit 52 at the relevant time.

The tone voltage generation circuit 60 is configured by 63 voltage dividing resistors connected in series between high voltage VDH and low voltage VDL, and generates tone voltages V1 to V64 of 64 steps.

The decode circuit 70 decodes the display signal SIG held in the data latch circuit 54, and selects and outputs the voltage to be output to each decode output node Nd₁, Nd₂, . . . (collectively referred to as “decode output node Nd”) based on the decoded result from the tone voltages V1 to V64.

As a result, the display voltage (one of the tone voltages V1 to V64) corresponding to the display signal SIG worth of one pixel line held in the data latch circuit 54 is simultaneously (in parallel) output to the decode output node Nd. In FIG. 1, the decode output nodes Nd₁, Nd₂ corresponding to the data lines DL₁, DL₂ of the first and second columns are shown by way of example.

The analog amplifier 80 outputs the analog voltage corresponding to each display voltage output to the decode output nodes Nd₁, Nd₂, from the decode circuit 70 to each data line DL₁, DL₂, . . . .

The source driver 40 repeatedly outputs the display voltage corresponding to a series of display signal SIG to the data line DL by one pixel line based on the predetermined scanning period, and the gate line driving circuit 30 drives the gate lines GL₁, GL₂, . . . in this order or in the reverse order in synchronization with the scanning period, thereby displaying the image or the inverted image based on the display signal SIG on the liquid crystal array section 20.

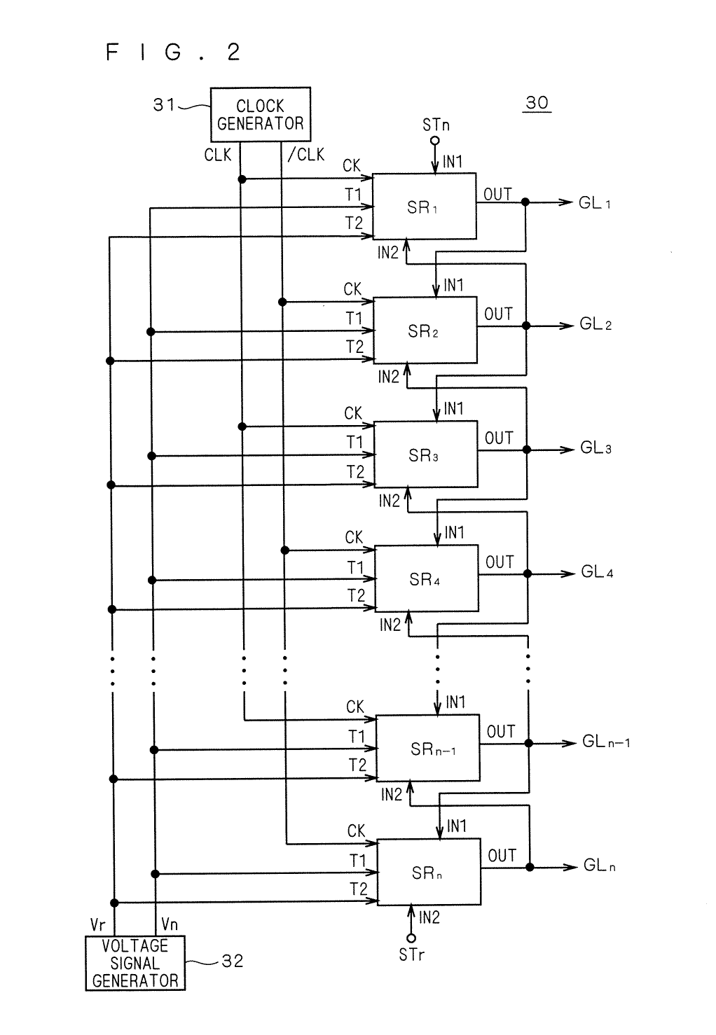

A conventional gate line driving circuit 30 and a bi-directional unit shift register configuring the same will now be described to simplify the explanation of the present invention. FIG. 2 is a view showing a configuration of a conventional gate line driving circuit 30. The gate line driving circuit 30 is configured by the bi-directional shift register comprising a plurality of stages. That is, the relevant gate line driving circuit 30 includes n cascade connected bi-directional unit shift registers SR₁, SR₂, SR₃, . . . , SRₙ (the unit shift registers SR₁, SR₂, SR₃, . . . , SRₙ hereinafter collectively referred to as “unit shift register SR”). One unit shift register SR is arranged for one pixel line, that is, one gate line GL.

A clock generator 31 shown in FIG. 2 inputs two phase clock signals CLK, /CLK having phases different from each other to the unit shift register SR of the gate line driving circuit 30. The clock signals CLK, /CLK are controlled so as to be alternately activated at the timing synchronized with the scanning period of the display apparatus.

A voltage signal generator 32 shown in FIG. 2 generates a first voltage signal Vn and a second voltage signal Vr to determine the shift direction of the signal in the bi-directional shift register. The first voltage signal Vn and the second voltage signal Vr are signals complementary to each other, and the voltage signal generator 32 has the first voltage signal Vn at H level and the second voltage signal Vr at L level when shifting the signal in the direction from the previous stage to the subsequent stage (order of unit shift registers SR₁, SR₂, SR₃, . . . ) (this direction is defined as “forward direction”). On the contrary, the second voltage signal Vr is at H level and the first voltage signal Vn is at L level when shifting the signal in the direction from the subsequent stage to the previous stage (order of unit shift registers SRₙ, SRₙ₋₁, SRₙ₋₂, . . . ) (this direction is defined as “reverse direction”).

Each unit shift register SR includes a first input terminal IN1, a second input terminal IN2, an output terminal OUT, a clock terminal CK, a first voltage signal terminal T1 and a second voltage signal terminal T2. One of the clock signals CLK, /CLK is input so that the clock signal different from the unit shift register SR adjacent before and after is input to the clock terminal CK of each unit shift register SR, as shown in FIG. 2.

The clock signals CLK, /CLK generated by the clock generator 31 are able to interchange the phase with each other according to the shift direction of the signal by program or by change of connection of the wiring. Interchange by change of connection of the wiring is effective when fixing the shift direction to one direction before manufacturing the display apparatus. Interchange by program is effective when fixing the shift direction to one direction after manufacturing the display apparatus or allowing the shift direction to be changed while using the display apparatus.

The gate line GL is connected to the output terminal OUT of the unit shift register SR. In other words, the signal (output signal) output to the output terminal OUT becomes a horizontal (or vertical) scanning pulse for activating the gate line GL.

A first control pulse STn is input to the first input terminal IN1 of the unit shift register SR₁ of the first stage, which is the leading stage. The first control pulse STn becomes the start pulse corresponding to the head of each frame period of the image signal in the forward shift, and becomes the end pulse corresponding to the end of each frame period of the image signal in the reverse shift. The first input terminal IN1 of the unit shift register SR of the second and subsequent stages is connected to the output terminal OUT of the unit shift register SR of the previous stage. That is, the output signal of the previous stage is input to the first input terminal IN1 of the unit shift register SR for the second and subsequent stages.

The second control pulse STr is input to the second input terminal IN2 of the n^{th} (n^{th} stage) unit shift register SRn, which is the final stage. The second control pulse STr becomes the start pulse in the reverse shift, and becomes the end pulse in the forward shift. The second input terminal IN2 before k−1^{th} stage is connected to the output terminal OUT of the subsequent stage. That is, the output signal of the subsequent stage is input to the second input terminal IN2 of the second and subsequent stages.

Each unit shift register SR transmits the input signal (output signal of previous stage) input from the previous stage to the corresponding gate line GL and the unit shift register SR of the next stage while shifting the same in the forward shift in synchronization with the clock signals CLK, /CLK. In the reverse shift, the input signal (output signal of subsequent stage) input from the subsequent stage is transmitted to the corresponding gate line GL and the unit shift register SR of the previous stage while shifting the same (operation of the unit shift register SR to be hereinafter described in detail). As a result, a series of unit shift registers SR function as a so-called gate line driving unit for sequentially activating the gate line GL at the timing based on a predetermined scanning period.

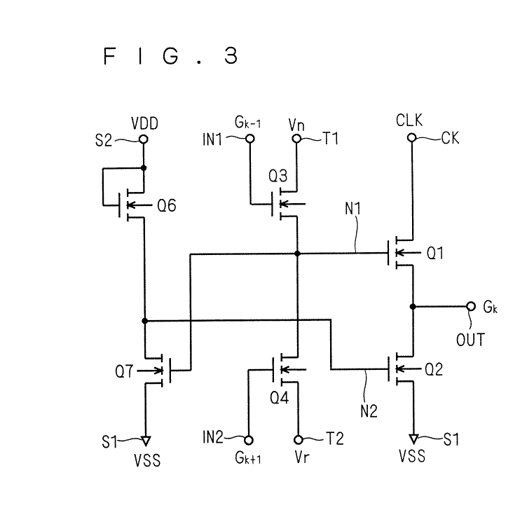

FIG. 3 is a circuit diagram showing a configuration of the conventional bi-directional unit shift register SR similar to that disclosed in patent document 1. The configuration of each cascade connected unit shift register SR is substantially all the same in the gate line driving circuit 30, and thus only the configuration of one unit shift register SR will be described below by way of example. The transistors configuring the unit shift register SR are all field effect transistors of the same conductivity type but are assumed to be all N-type TFT in the present embodiment.

As shown in FIG. 3, the conventional bi-directional unit shift register SR includes a first power supply terminal S1 supplied with low potential side power supply potential VSS and a second power supply terminal S2 supplied with high potential side power supply potential VDD in addition to the first and second input terminals IN1, IN2, the output terminal OUT, the clock terminal CK, and first and second voltage signal terminals T1, T2, as already shown in FIG. 2. In the following description, the low potential side power supply potential VSS is assumed as the 8 reference potential (=0V) of the circuit, but in actual use, the reference potential is set with the voltage of the data written to the pixel as the reference, and for example, the high potential side power supply potential VDD is set at 17V and the low potential side power supply potential VSS is set at −12V etc.

The output stage of the unit shift register SR is configured by a transistor Q1 connected between the output terminal OUT and the clock terminal CK, and a transistor Q2 connected between the output terminal OUT and the first power supply terminal S1. That is, the transistor Q1 is an output pull-up transistor for supplying the clock signal input to the clock terminal CK to the output terminal OUT, and the transistor Q2 is an output pull-down transistor for supplying the potential of the first power supply terminal S1 to the output terminal OUT. The node connected by the gate (control electrode) of the transistor Q1 configuring the output stage of the unit shift register SR is defined as node N1 and the gate node of the transistor Q2 as node N2.

A transistor Q3 is connected between the node N1 and the first voltage signal terminal T1, the gate of which is connected to the first input terminal IN1. A transistor Q4 is connected between the node N1 and the second voltage signal terminal T2, the gate of which is connected to the second input terminal IN2.

A transistor Q6 is connected between the node N2 and the second power supply terminal S2, and a transistor Q7 is connected between the node N2 and the first power supply terminal S1. The gate of the transistor Q6 is connected to the second power terminal S2 similar to the drain, or is a so-called diode connected. The gate of the transistor Q7 is connected to the node N1. The transistor Q7 has a driving ability (ability to flow current) set sufficiently higher than the transistor Q6. That is, the on-resistance of the transistor Q7 is smaller than the on-resistance of the transistor Q6. Thus, when the gate potential of the transistor Q7 rises, the potential of the node N2 lowers, whereas when the gate potential of the transistor Q7 lowers, the potential of the node N2 rises. That is, the transistor Q6 and the transistor Q7 configure an inverter having the node N1 as the input end and the node N2 as the output end. The relevant inverter is a so-called “ratio type inverter”, in which the operation is defined by the ratio of the on-resistance values of the transistor Q6 and the transistor Q7. The inverter functions as a “pull-down driving circuit” for driving the transistor Q2 to pull-down the output terminal OUT.

The operation of the unit shift register SR of FIG. 3 will now be described. The operation of each unit shift register SR configuring the gate line driving circuit 30 is substantially all the same, and thus the operation of the k^{th} unit shift register SRₖ will be described herein by way of example.

The following description is given assuming the clock signal CLK is input to the clock terminal CK of the relevant shift register SRₖ for the sake of simplification (e.g., correspond to unit shift register SR₁, SR₃ etc. in FIG. 2). Furthermore, the output signal of the relevant unit shift register SRₖ is defined as Gₖ, the output signal of the unit shift register SRₖ₋₁ of the previous stage (k−1 stage) as Gₖ₋₁, and the output signal of the unit shift register SRₖ₊₁ of the next stage (k+1 stage) as Gₖ₊₁. The potential of H level of the clock signals CLK, /CLK, the first voltage signal Vn, and the second voltage signal Vr is assumed to be equal to the high potential side power supply potential VDD. Moreover, the threshold voltage of each transistor configuring the unit shift register SR is assumed to be all the same, where the value thereof is Vth.

A case in which the gate line driving circuit 30 performs the operation of the forward shift will be described first. The voltage signal generator 32 has the first voltage signal Vn at H level (VDD) and the second voltage signal Vr at L level (VSS). That is, the transistor Q3 functions as a transistor for charging (pulling up) the node N1, and the transistor Q4 functions as a transistor for discharging (pulling down) the node N1 in the forward shift.

The node N1 is assumed to be at L level (VSS) and the node N2 at H level (NDD-Nth) in the initial state (this state is hereinafter referred to as “greset state”). The clock terminal CK (clock signal CLK), the first input terminal IN1 (output signal Gₖ₋₁ of previous stage) and the second input terminal IN2 (output signal Gₖ₊₁ of next stage) are all assumed to be at L level. Since the transistor Q1 is turned OFF (shielded state), and the transistor Q2 is turned ON (electrically conducted state) in the reset state, the output terminal OUT (output signal Gk) is maintained at L level irrespective of the level of the clock terminal CK (clock signal CLK). That is, the gate line GLₖ to be connected with the relevant unit shift register SRₖ is in the non-selective state.

When the output signal Gₖ₋₁ of the unit shift register SRₖ₋₁ of the previous stage (first control pulse STn serving as start pulse for the first stage) becomes H level from the above state, the relevant output signal is input to the first input terminal IN1 of the relevant unit shift register SRₖ and the transistor Q3 is turned ON, and the node N1 becomes H level (VDD). The transistor Q7 is accordingly turned ON, and thus the node N2 becomes L level (VSS). In the state in which the node N1 is at H level and the node N2 is at L level (this state is hereinafter referred to as “set state”), the transistor Q1 is turned ON and the transistor Q2 is turned OFF. Subsequently, when the output signal Gₖ₋₁ of the previous stage returns to L level, the transistor Q3 is turned OFF, but the node N1 becomes H level of the floating state, and thus the set state is maintained.

Subsequently, the clock signal CLK input to the clock terminal CK becomes H level, but since the transistor Q1 is turned ON and the transistor Q2 is turned OFF at this point, the level of the output terminal OUT rises therewith. The level of the node N1 in the floating state is boosted by a predetermined voltage due to coupling via gate-channel capacity of the transistor Q1. Therefore, the driving ability of the transistor Q1 is maintained high even if the level of the output terminal OUT rises, and thus the level of the output signal Gₖ changes following the level of the clock terminal CK. In particular, when the gate-source voltage of the transistor Q1 is sufficiently large, the transistor Q1 performs the operation in the non-saturated region (non-saturated operation), and thus the loss worth of threshold voltage does not exist, and the output terminal OUT rises to the same level as the clock signal CLK. Therefore, the output signal Gₖ becomes H level by the period the clock signal CLK is at H level, and the gate line GLₖ is activated and in the selected state.

Subsequently, when the clock signal CLK returns to L level, the output signal Gₖ also becomes L level following thereto, and the gate line GLₖ is discharged and returned to the non-selected state.

The output signal Gₖ is input to the first input terminal IN1, and thus the output signal Gₖ₊₁ of the next stage becomes H level at the timing the clock signal/CLK becomes H level. The transistor Q4 of the relevant unit shift register SRₖ is thus turned ON, and the node N1 becomes L level. The transistor Q7 is accordingly turned OFF and the node N2 becomes H level. That is, the state returns to the reset state in which the transistor Q1 is turned OFF, and the transistor Q2 is turned ON.

Subsequently, when the output signal Gₖ₊₁ of the next stage returns to L level, the transistor Q4 is turned OFF, but since the transistor Q3 is also turned OFF at this point, the node N1 becomes the floating state, and the L level is maintained. This state continues until the signal is input to the first input terminal IN1, and the relevant unit shift register SRₖ is maintained in the reset state.

Summarizing the operation of the forward shift described above, the unit shift register SR maintains the reset state while the signal (start pulse or output signal Gₖ₋₁ of the previous stage) is not input to the first input terminal IN1. Since the transistor Q1 is turned OFF and the transistor Q2 is turned ON in the reset state, the output terminal OUT (gate line GLₖ) is maintained at L level (VSS) of low impedance. When the signal is input to the first input terminal IN1, the unit shift register SR switches to the set state. Since the transistor Q1 is turned ON and the transistor Q2 is turned OFF in the set state, the output terminal OUT becomes H level and the output signal Gₖ is output during the period the signal (clock signal CLK) of the clock terminal CK is at H level. Thereafter, when the signal (output signal Gₖ₊₁ of the next stage or end pulse) is input to the second input terminal IN2, the state returns to the original reset state.

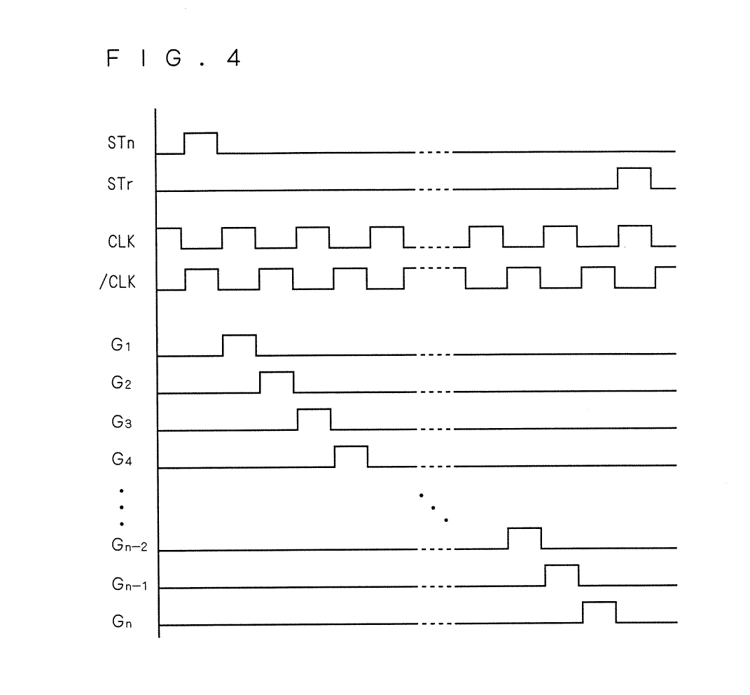

If the plurality of unit shift registers SR operating in this manner are cascade connected as in FIG. 2 to configure the gate line driving circuit 30, the first control pulse STn serving as the start pulse input to the first input terminal IN1 of the unit shift register SR₁ of the first stage is transmitted in the order of unit shift register SR₂, SR₃, . . . while being shifted at a timing synchronized with the clock signals CLK, /CLK as shown in the timing chart of FIG. 4. The gate line driving circuit 30 thereby drives the gate lines GL₁, GL₂, GL₃, . . . in this order at a predetermined scanning period.

In the forward shift, the second control pulse STr serving as the end pulse must be input to the second input terminal IN2 of the relevant unit shift register SRₙ immediately after the unit shift register SRₙ of the final stage outputs the output signal Gn, as shown in FIG. 4. The relevant unit shift register SRₙ is thereby returned to the set state.

On the other hand, when the gate line driving circuit 30 performs the operation of the reverse shift, the voltage signal generator 32 turns the first voltage signal Vn to L level (VSS) and the second voltage signal Vr to H level (VDD). That is, the transistor Q3 functions as the transistor for discharging (pulling down) the node N1 and the transistor Q4 functions as the transistor for charging (pulling up) the node N1 in the reverse shift, in contradiction to the forward shift. The second control pulse STr is input to the second input terminal IN2 of the unit shift register SRₙ of the final stage as start pulse, and the first control pulse STn is input to the first input terminal IN1 of the unit shift register SR₁ of the first stage as the end pulse. Therefore, the operation of the transistor Q3 and the transistor Q4 is interchanged with each other with respect to the forward shift in the unit shift register SR of each stage.

Therefore, in the reverse shift, the unit shift register SR maintains the reset state while the signal (start pulse or output signal Gₖ₊₁ of the next stage) is not input to the second input terminal IN2. Since the transistor Q1 is turned OFF and the transistor Q2 is turned ON in the reset state, the output terminal OUT (gate line GLₖ) is maintained at L level (VSS) of low impedance. When the signal is input to the second input terminal IN2, the unit shift register SR switches to the set state. Since the transistor Q1 is turned ON and the transistor Q2 is turned OFF in the set state, the output terminal OUT becomes H level and the output signal Gₖ is output during the period the signal (clock signal CLK) of the clock terminal CK is at H level. Thereafter, when the signal (output signal Gₖ₋₁ of the previous stage or end pulse) is input to the first input terminal IN1, the state returns to the original reset state.

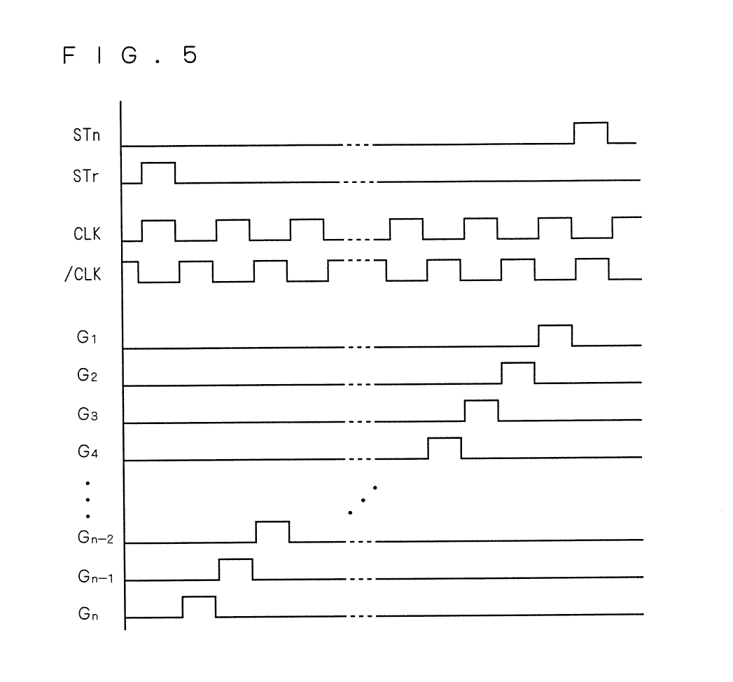

If the plurality of unit shift registers SR operating in this manner are cascade connected as in FIG. 2 to configure the gate line driving circuit 30, the second control pulse STr serving as the start pulse input to the second input terminal IN2 of the unit shift register SRₙ of the final stage (n^{th} stage) is transmitted in the order of unit shift register SRₙ₋₁, SRₙ₋₂, . . . while being shifted at a timing synchronized with the clock signals CLK, /CLK as shown in the timing chart of FIG. 5. The gate line driving circuit 30 thereby drives the gate lines GLₙ, GLₙ₋₁, GLₙ₋₂ . . . in this order, that is, the order opposite the forward shift, at a predetermined scanning period.

In the reverse shift, the first control pulse STn serving as the end pulse must be input to the first input terminal IN1 of the relevant unit shift register SR₁ immediately after the unit shift register SR₁ of the first stage outputs the output signal G₁, as shown in FIG. 5. The relevant unit shift register SR₁ is thereby returned to the set state.

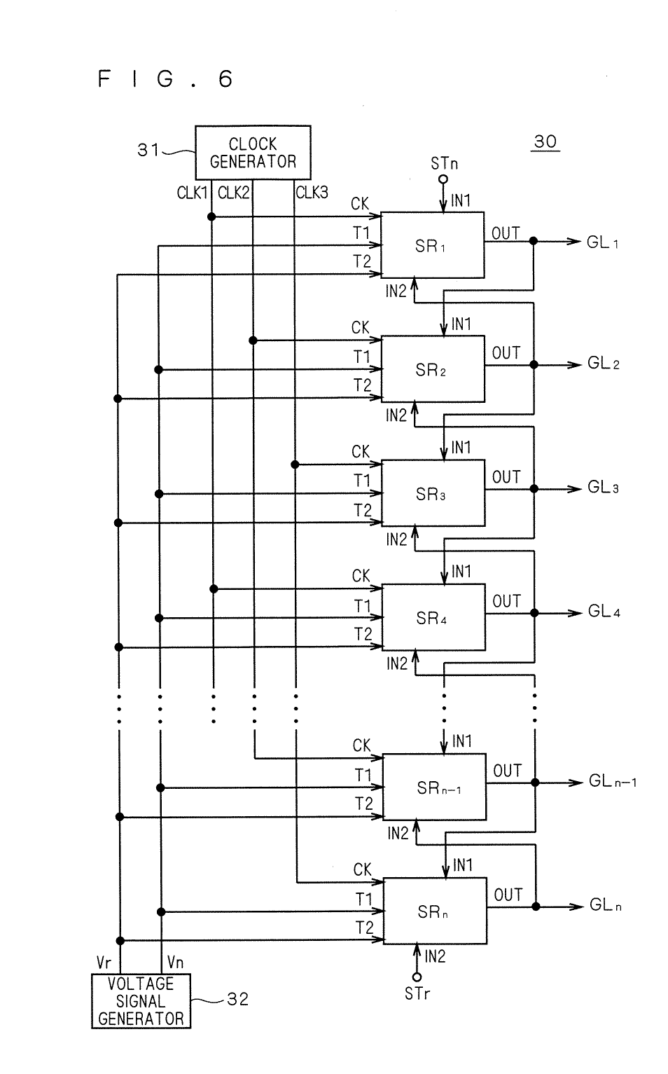

An example in which a plurality of unit shift registers SR operate based on two phase clocks has been described in the above example, but may be operated using three phase clock signals. In this case, the gate line driving circuit 30 may be configured as shown in FIG. 6.

The clock generator 31 in this case outputs clock signals CLK1, CLK2, and CLK 3, which are three phase clocks having different phases. One of the clock signals CLK1, CLK2, and CLK 3 is input to the clock terminal CK of each unit shift register SR so that clock signals different to each other are input to unit shift registers SR adjacent before and after. The order of becoming H level can be changed within the clock signals CLK1, CLK2, and CLK 3 according to the direction of shifting the signal by program or change of connection of the wiring. For example, the signals become H level in the order of CLK1, CLK2, CLK3, CLK1, . . . in the forward shift, and become H level in the order of CLK3, CLK2, CLK1, CLK3, . . . , in the reverse shift.

The operation of the individual unit shift register SR is the same for the gate line driving circuit 30 configured as in FIG. 6 as in the case of FIG. 2 described above, and thus the description thereof will be omitted.

In the gate line driving circuit 30 configured as in FIGS. 2 and 6, each unit shift register SR cannot be in the reset state (i.e., initial state) unless after the unit shift register SR of the next stage has operated at least once in the forward shift, for example. In the reverse shift, on the other hand, each unit shift register SR cannot be in the reset state unless after the unit shift register SR of the previous stage has operated at least once. Each unit shift register SR cannot perform the normal operation unless after the reset state. Therefore, the dummy operation of transmitting a dummy input signal from the first stage to the final stage (or from final stage to first stage) of the unit shift register SR must be performed, prior to the normal operation. Alternatively, a reset transistor may be separately arranged between the node N2 and the second power supply terminal S2 (high potential side power supply) of each unit shift register SR, and the reset operation of forcibly charging the node N2 may be performed before the normal operation. In this case, however, the reset signal line must be separately arranged.

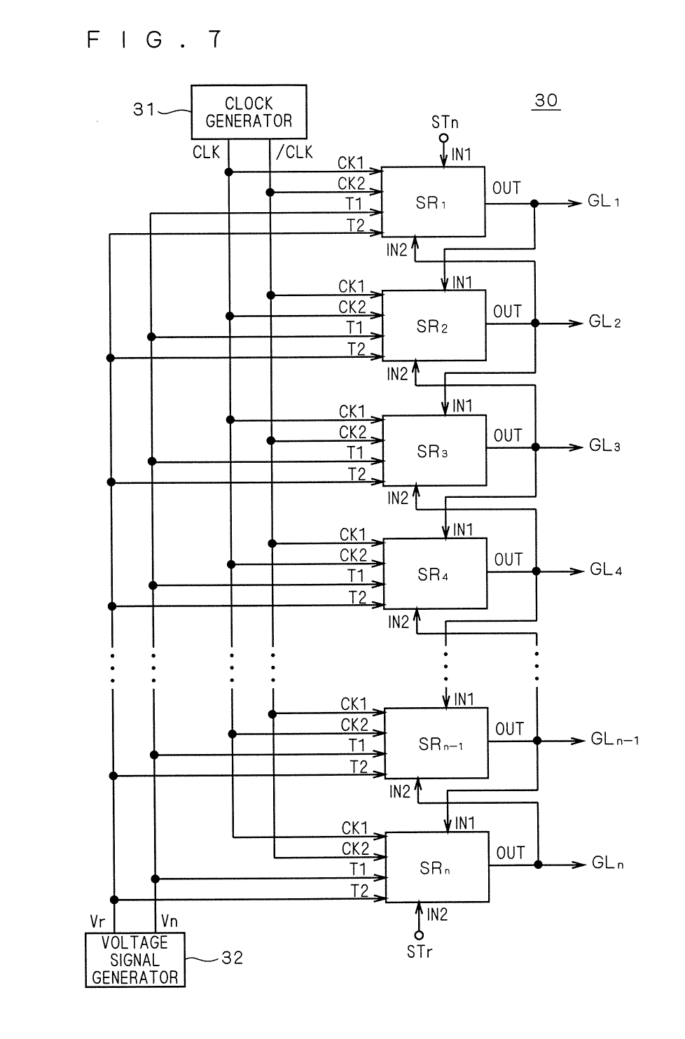

The gate line driving circuit 30 according to the present invention and the bi-directional unit shift register configuring the same will now be described. FIG. 7 is a view showing the configuration of the gate line driving circuit 30 according to the first embodiment. The gate line driving circuit 30 also comprises a shift register of a plural stages configured by a plurality of cascade connected bi-directional unit shift registers SR₁, SR₂, SR₃, SR₄, . . . SRₙ.

As shown in FIG. 7, each unit shift register SR of the first embodiment includes a first input terminal IN1, a second input terminal IN2, an output terminal OUT, a first clock terminal CK1, a second clock terminal CK2, a first voltage signal terminal T1 and a second voltage signal terminal T2. One of the clock signals CLK, /CLK output by the clock generator 31 is input to the first and second clock terminals CK1, CK2 of each unit shift register.

In FIG. 7, a first control pulse STn is input to the first input terminal IN1 of the unit shift register SR₁ of the first stage which is the leading stage. The first control pulse STn acts as a start pulse corresponding to the head of each frame period of the image signal in the forward shift, and acts as an end pulse corresponding to the end of each frame period of the image signal in the reverse shift. The output signal of the previous stage is input to the first input terminal IN1 of the unit shift register SR of the second and subsequent stages.

A second control pulse STr is input to the second input terminal of the unit shift register SRn of the n^{th} stage which is the final stage. The second control pulse STr becomes the start pulse in the reverse shift and becomes the end pulse in the forward shift. The output signal of the subsequent stage is input to the second input terminal IN2 before n−1^{th} stage.

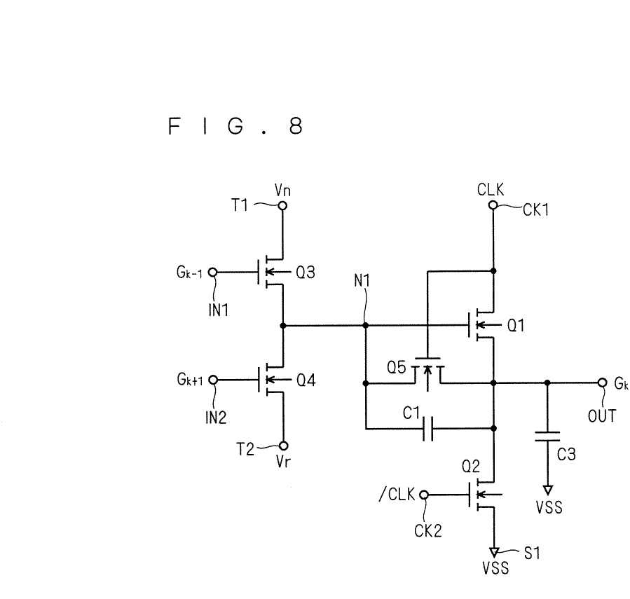

FIG. 8 is a circuit diagram showing the configuration of the bi-directional unit shift register SR according to the first embodiment. The configuration of one unit shift register SR will be described by way of example. The transistors configuring the unit shift register SR are all assumed to be N-type a-Si TFT. However, the application of the present invention is not limited to a-Si TFT, and the present invention is also applicable to those configured with MOS transistor, organic TFT and the like.

As shown in FIG. 8, the output stage of the unit shift register SR is configured by a transistor Q1 connected between the output terminal OUT and the first clock terminal CK1, and a transistor Q2 connected between the output terminal OUT and the first power supply terminal S1. That is, the transistor Q1 is an output pull up transistor (first transistor) for providing the clock signal input to the first clock terminal CK 1 to the output terminal OUT, and the transistor Q2 is an output pull down transistor (second transistor) for discharging the output terminal OUT by supplying the potential (low potential side power supply potential VSS) of the first power supply terminal S1 to the output terminal OUT. The node connected with the gate (control electrode) of the transistor Q1 is defined as node N1 (first node), as shown in FIG. 8. The gate of the transistor Q2 is connected to the second clock terminal CK2.

The unit shift register SR according to the present embodiment includes a transistor Q5 (fifth transistor) connected between the gate and the source of the transistor Q1 (i.e., between the output terminal OUT and the node N1), the gate of which transistor Q5 is connected to the first clock terminal CK1. That is, the transistor Q5 functions as a switching circuit for electrically conducting the node N1 and the output terminal OUT based on the signal input to the first clock terminal CK1. Similarly, a capacitive element C1 is arranged parallel to the transistor Q5 between the node N1 and the output terminal OUT. The element of reference character “C3” indicates the load capacitance of the output terminal (i.e., gate line) of the unit shift register SR.

The transistor Q3 is connected between the node N1 and the first voltage signal terminal T1, and the gate of the transistor Q3 is connected to the first input terminal IN1. The transistor Q4 is connected between the node N1 and the second voltage signal terminal T2, and the gate of the transistor Q4 is connected to the second input terminal IN2. That is, the transistor Q3 is a third transistor for providing the first voltage signal Vn to the node N1 based on the signal (first input signal) input to the first input terminal IN1. The transistor Q4 is a fourth transistor for providing the second voltage signal Vr to the node N1 based on the signal (second input signal) input to the second input terminal IN2. In other words, the transistors Q3, Q4 configure a drive circuit for driving the transistor Q1. The first voltage signal Vn and the second voltage signal Vr are signals complementary to each other, and when the shift direction of the signal is a direction from the previous stage to the subsequent stage (order of unit shift registers SR₁, SR₂, SR₃, . . . ,) (this direction is defined as “forward direction”), as described above, the voltage signal generator 32 has the first voltage signal Vn at H level and the second voltage signal Vr at L level. On the contrary, the second voltage signal Vr is at H level and the first voltage signal Vn is at L level when the shift direction of the signal is a direction from the subsequent stage to the previous stage (order of unit shift registers SRₙ, SRₙ₋₁, SRₙ₋₂, . . . ) (this direction is defined as “reverse direction”).

The operation of the bi-directional unit shift register SR according to the first embodiment will now be described. The unit shift register SR of FIG. 8 is assumed to be configuring the gate line driving circuit 30 by being cascade connected as in FIG. 7. The operation of the unit shift register SRₖ of the k^{th} stage will be described by way of example for simplification, where the clock signal CLK is input to the first clock terminal CK1 of the unit shift register SRₖ and the clock signal /CLK is input to the second clock terminal CK2. The output signal of the unit shift register SRₖ is defined as Gₖ, the output signal of the unit shift register SRₖ₋₁ of the previous stage (k−1^{th} stage) is defined as Gₖ₋₁, and the output signal of the unit shift register SRₖ₊₁ of the next stage (k+1^{th} stage) is defined as Gₖ₊₁.

The voltage of H level of the clock signals CLK, /CLK as well as first and second voltage signals Vn, Vr are equal to each other, and the value thereof is assumed to be VDD. In the present embodiment, the threshold voltage of each transistor Qm configuring the unit shift register SR is expressed as Vth(Qm).

A case of when the gate line driving circuit 30 performs the operation of the forward shift will be described. That is, the first voltage signal Vn generated by the voltage signal generator 32 is at H level (VDD), and the second voltage signal Vr is at L level (VSS).

### (A) Operation in Gate Line Selection

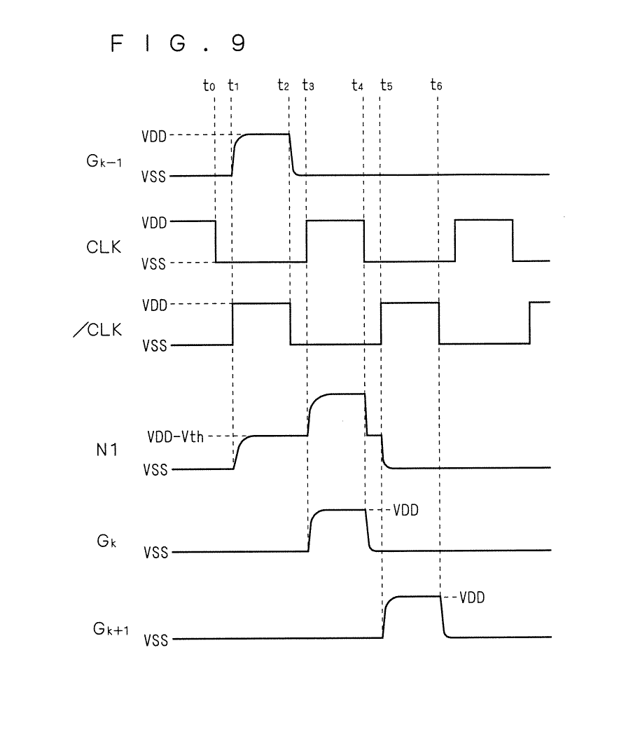

First, the operation of when the output signal Gₖ₋₁ of the previous stage (first control pulse STn serving as start pulse for the unit shift register SR1 of first stage) is input to the first input terminal IN1 of the unit shift register SRₖ of FIG. 8, and the unit shift register SRₖ outputs the output signal Gₖ (i.e., when activating gate line GLₖ) will be described. FIG. 9 is a timing chart showing the relevant operation.

The node N1 is at L level (VSS) (hereinafter referred to as “reset state”) in the initial state. The first clock terminal CK1 (clock signal CLK) is at H level, and the second clock terminal CK2 (clock signal /CLK), the first input terminal IN1 (output signal Gₖ₋₁ of previous stage) and the second input terminal IN2 (output signal Gₖ₊₁ of next stage) are at L level. The transistors Q1 to Q4 are turned OFF in this initial state, and thus the node N1 and the output terminal OUT (output signal Gₖ) are at L level of floating state.

After the clock signal CLK transfers to L level at time t₀, the output signal Gₖ₋₁ of the previous stage becomes H level at time t₁ at when the clock signal /CLK transfers to H level, whereby the transistor Q3 is turned ON. The node N1 is charged and becomes H level (VDD-Vth(Q3)) since the first voltage signal Vn is at H level. The transistor Q1 is thereby turned ON. The clock signal CLK is at L level (VSS), and the clock signal /CLK is H level and thus the transistor Q2 is turned ON, whereby the output signal Gₖ maintains L level.

Thereafter, the output signal Gₖ₋₁ of the previous stage returns to L level at time t₂ at when the clock signal /CLK becomes L level. The transistor Q3 is thereby turned OFF, and thus the node N1 is at H level of floating state. The transistor Q2 is also turned OFF, but the output signal Gk maintains L level since the transistor Q1 maintains ON state and the first clock terminal CK1 (clock signal CLK) is at L level.

The clock signal CLK is provided to the output terminal OUT since the transistor Q1 is turned ON at time t₃ at when the clock signal CLK becomes H level, and the level of the output signal Gₖ rises. The node N1 is boosted according to the rise in level of the output signal Gₖ by the boosting capacitor C1 and the capacitance coupling via gate-channel capacity of the transistor Q1. Therefore, the gate-source voltage of the transistor Q1 is maintained large even if the output signal Gₖ becomes H level, and the driving ability of the transistor Q1 is ensured. Furthermore, since the transistor Q1 operates in an unsaturated manner, the level of the output terminal OUT (output signal Gₖ) becomes VDD, which is the same as the H level of the clock signal CLK, the load capacitor C3 is charged and the gate line GLₖ becomes a selected state.

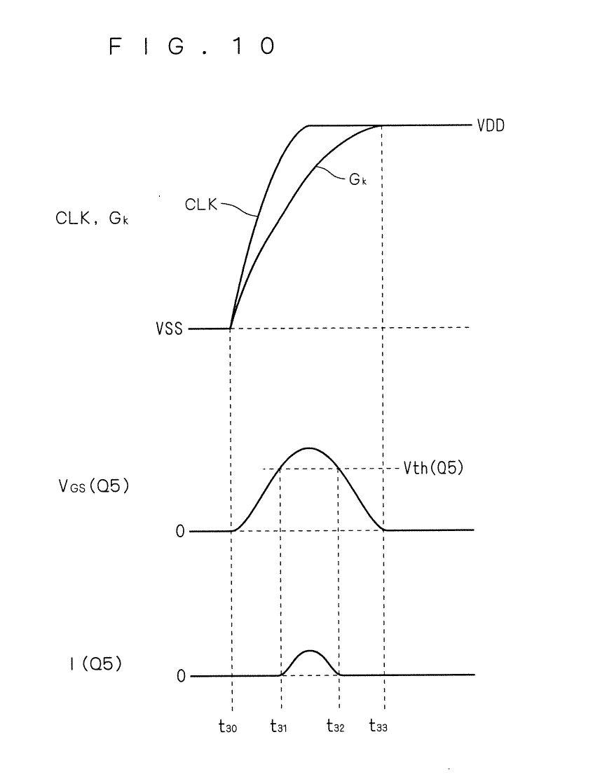

The clock signal CLK is provided to the gate of the transistor Q5 in the unit shift register SRₖ of FIG. 8. The operation of the transistor Q5 at time t₃, that is, at the rise of the output signal Gₖ will now be described. FIG. 10 is a view showing the operation, where the figure on the upper stage is a view showing in an enlarged manner the waveform of the clock signal CLK and the output signal Gₖ at time t₃ of FIG. 9. The figured on the middle stage of FIG. 10 shows the gate-source voltage V_{GS}(Q5) of the transistor Q5, that is, the voltage difference between the clock signal CLK and the output signal Gₖ of the upper stage (source of transistor Q5 is output terminal OUT side, drain is node N1 side from potential relationship at the rise of the output signal Gk). The lower stage of FIG. 10 shows the current I(Q5) flowing through the transistor Q5.

When the clock signal CLK starts to rise at time t₃ (time t₃₀ in FIG. 10), the output signal Gₖ also rises following thereto. Since a slight difference is created in the rising speed between the clock signal CLK and the output signal Gₖ, as shown in the upper stage of FIG. 10, a potential difference is created between the signals from time t₃₀ to time t₃₃ at when the output signal Gₖ becomes the same level as the clock signal CLK. That is, the voltage V_{GS}(Q5), as shown in middle stage of FIG. 10, is applied between the gate and the source of the transistor Q5 during time t₃₀ to t₃₃. Assume the gate-source voltage V_{GS}(Q5) of the transistor Q5 exceeds the threshold voltage Vth(Q5) of the transistor Q5 only during period t₃₀ to t₃₃. The transistor Q5 is thereby turned ON (electrically conducted state), and thus the current I(Q5), a shown in lower stage of FIG. 10, flows from the node N1 to the output terminal OUT. The current I(Q5) becomes a part of the current for charging the load capacitor C3.

In the unit shift register SRₖ, the advantage that the driving ability of the transistor Q1 can be ensured by boosting the node N1 at the rise of the output signal Gₖ, but such advantage lowers since the rise in potential of the node N1 is suppressed when the current I(Q5) becomes large. However, since the transistor Q1 has a large size, the output signal Gₖ rapidly rises following the clock signal CLK, and thus the voltage V_{GS}(Q5) is basically not too large, and even if the voltage V_{GS}(Q5) exceeds the threshold voltage Vth(Q5), it is only for a short period of time. Thus, only a small amount of the current I(Q5) flows, the level of the node N1 does not lower to an extent of affecting the driving ability of the transistor Q1. Obviously, if the gate-source voltage V_{GS}(Q5) of the transistor Q5 does not exceed the threshold voltage Vth(Q5), the transistor Q5 is not turned ON, the current I(Q5) does not flow, and the driving ability of the transistor Q1 is not affected at all.

Therefore, since the node N1 is sufficiently boosted in time of rise of level of the output signal Gₖ, large driving ability of the transistor Q1 is widely ensured, and the output signal Gₖ rises at high speed at time t₃.

If the level of the output signal Gₖ rises sufficiently (from time t₃₂ in FIG. 10), the transistor Q5 is turned OFF and the current does not flow (i.e., I(Q5)=0), the gate-source voltage of the transistor Q1 is maintained, and the driving ability of the transistor Q1 is ensured. Therefore, the output terminal OUT (gate line GLₖ) is rapidly discharged through the transistor Q1, and the output signal Gₖ returns to L level at time t₄ (FIG. 9) at when the clock signal CLK becomes L level next.

The output signal Gₖ₊₁ of the shift register of the next stage becomes H level at time t₅ at when the clock signal /CLK becomes H level, and the transistor Q4 is turned ON. Since the second voltage signal Vr is at L level, the node N1 is discharged and becomes L level, and the relevant unit shift register SRₖ returns to the reset state. The transistor Q1 is thereby turned OFF but the transistor Q2 is turned ON since the clock signal /CLK is at H level, and the L level of the output signal Gₖ is maintained.

### (B) Operation in Non-Selective Period of Gate Line

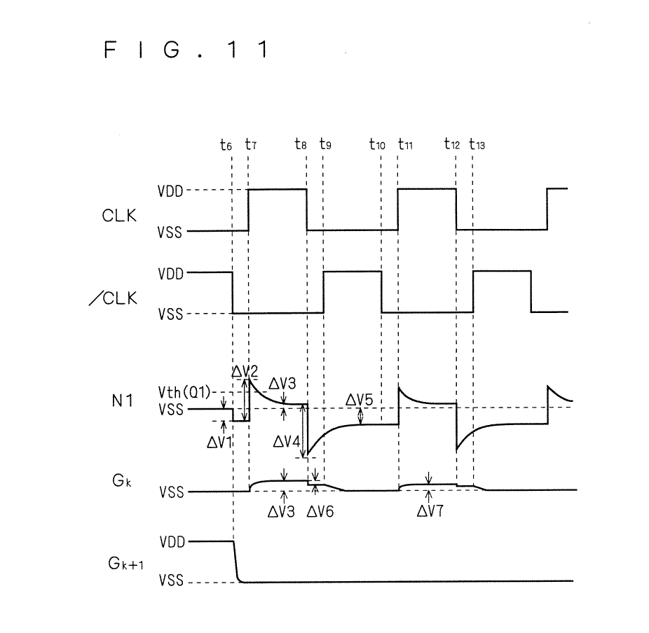

The operation of the non-selective period (i.e., period maintaining the gate line GLₖ in an inactivated state) in the unit shift register SRₖ will now be described. FIG. 11 is a timing chart showing the relevant operation, and shows each signal waveform of when transitioning to the non-selective period after the unit shift register SRₖ outputs the output signal Gₖ. That is, time t₆ of FIG. 11 corresponds to time t₆ shown in FIG. 9. As described in FIG. 9, the clock signal /CLK and the output signal Gₖ₊₁ of the next stage become H level at time t₅, at which point, the node N1 and the output terminal OUT (output signal Gₖ) are at L level.

When the output signal Gₖ₊₁ of the next stage becomes L level at time t₆ at when the clock signal /CLK becomes L level, the transistor Q4 is turned OFF and the node N1 becomes L level of floating state. The level of the node N1 lowers by a specific voltage (ΔV1) by the coupling via overlapping capacitance between the gate and the drain of the transistor Q4. The transistor Q2 is also turned OFF when the clock signal /CLK becomes L level, and the output terminal OUT becomes L level of floating state.

When the clock signal CLK becomes H level at time t₇, the level of the node N1 rises by a specific voltage (ΔV2) by the coupling via overlapping capacitance between the gate and the drain of the transistor Q1. Assuming the potential of the node N1 has exceeded that threshold voltage Vth(Q1) of the transistor Q1, the transistor Q1 is turned ON during this time, and the current flows from the first clock terminal CK1 to the output terminal OUT. The charges are then accumulated in the load capacitor C3, and the level of the output terminal OUT (output signal Gₖ) starts to rise. However, the transistor Q5 is turned ON (electrically conducted state), and the charges of the relevant node N1 are immediately discharged to the load capacitor C3 even if the potential of the node N1 rises. Therefore, even if the transistor Q1 is turned ON by rise in level of the node N1, it is instantaneous, and furthermore, since the load capacitor C3 is relatively large, the rise in level of the output terminal OUT is very small (ΔV3). The node N1 of after being discharged through the transistor Q5 has the potential same as the output terminal OUT (potential higher by ΔV3 from VSS), but is maintained at L level.

When the clock signal CLK becomes L level at time t₈, the transistor Q5 is turned OFF. Since the node N1 is in floating state, the level of the node N1 lowers by a voltage (ΔV4) substantially the same as ΔV2 according to the fall of the clock signal CLK due to coupling via overlapping capacitance between the gate and the drain of the transistor Q1. When the gate-source voltages of the transistors Q3, Q4, Q5 exceed the threshold voltage as a result of lowering in the level of the node N1 (transistors Q3, Q4, Q5 all have the node N1 side as the source from potential relationship), the transistors are turned ON, and the level of the node N1 rises towards VSS. The rise in level of the node N1 terminates when all the transistors Q3, Q4, Q5 are turned OFF, and thus the potential of the node N1 becomes a potential lower by the minimum value (ΔV5) of the threshold voltages of the transistors Q3, Q4, Q5 with respect to the low potential side power supply potential VSS. According to the turning ON of the transistor Q5, the charges of the output terminal OUT flow into the node N1, and thus the level of the output terminal OUT lowers by a specific amount (ΔV6).

When the clock signal /CLK becomes H level at time t₉, the transistor Q2 is turned ON, the charges accumulated in the load capacitor C3 are discharged, and the level of the output signal OUT (output signal Gₖ) lowers towards VSS. When the clock signal /CLK becomes L level at time t₁₀, the transistor Q2 is turned OFF, and the output terminal OUT becomes L level of floating state.

The operations similar to in time t₇ to t₈ are performed in the subsequent time t₁₁ to t₁₂, but since the level (−ΔV5) of the node N1 immediately before time t₁₁ is lower than immediately before time t₇ (ΔV5>ΔV1), the level of the node N1 lowers by such amount. Accordingly, the amount of rise in level (ΔV7) of the output terminal OUT during time t₁₁ to t₁₂ also becomes a value lower than in time t₇ to t₈ (ΔV7<ΔV3).

The operations of time t₇ to t₁₂ are repeated until the selective period of the next gate line (i.e., until output signal Gₖ₋₁ of previous stage is input) from time t₁₂.

Therefore, there is barely no rise in the output signal Gₖ in the non-selective period in which the output signal Gₖ is not output (ΔV3 of FIG. 11 at maximum) in the unit shift register SRₖ of FIG. 8, and the malfunction is prevented.

As apparent from the description of (A) and (B) above, the node N1 is sufficiently boosted since the current does not flow to the transistor Q5 in time of output of the output signal Gₖ (in time of selection of gate line GLₖ) according to the bi-directional unit shift register SR according to the present embodiment, and the driving ability of the transistor Q1 is widely ensured. Thus, the rise and fall speed of the output signal Gₖ becomes faster, thereby contributing to higher speed of operation.

Since the transistor Q5 is turned ON every time the clock signal CLK becomes H level even if the level of the node N1 attempts to rise in rise of the clock signal CLK during the non-selective period in which the output signal Gₖ is not output, the charges involved in leakage current are discharged even if leakage current is generated at the transistor Q3, thereby maintaining L level. That is, the problem (first problem) of rise in potential of the node 1 caused by leakage current of the transistor Q3 in the non-selective period does not arise. In other words, the malfunction in the non-selective period is prevented and the reliability of operation of the image display apparatus is enhanced according to the unit shift register SR of the present embodiment.

In the case the gate line driving circuit 30 performs the operation of the reverse shift, on the other hand, the voltage signal generator 32 has the first voltage signal Vn at L level (VSS) and the second voltage signal Vr at H level (VDD). The second control pulse STr is input to the second input terminal IN2 of the unit shift register SRₙ of the final stage as the start pulse, and the first control pulse STₙ is input to the first input terminal IN1 of the unit shift register SR₁ of the first stage as the end pulse. The operations of the transistor Q3 and the transistor Q4 thereby interchange with each other in each unit shift register SR in contradiction to the forward shift, and the reverse shift becomes possible.

The basic operation of the unit shift register SR is the same as in the case of the forward shift even if the operations of the transistor Q3 and the transistor Q4 are interchanged, and thus the transistor Q5 also functions similar to in the case of the forward shift. Therefore, effects similar to the above are obtained even if the unit shift register SR of FIG. 8 performs the operation of reverse shift.

The clock signal /CLK is input to the gate of the transistor Q2 for pulling down the output terminal OUT in the bi-directional unit shift register SR of the present embodiment, and the gate is not continuously biased to positive as in the transistor Q2 of the conventional unit shift register shown in FIG. 3. Therefore, shift of the threshold voltage of the transistor Q2, that is, lowering in the driving ability of the transistor Q2 is suppressed, and the output terminal OUT is prevented from being in the floating state in the non-selective period. The potential of each gate line is thus prevented from becoming unstable, and the problem (fourth problem) of degradation of the display quality caused by malfunction is suppressed.

The capacitance element C1 of the unit shift register SR of FIG. 8 functions to boost the potential of the node N1 when the output terminal OUT becomes H level, as described above, in the selective period. In the non-selective period, the capacitance element C1 functions to suppress the potential of the node N1 from rising by overlapping capacitance between the gate and the drain of the transistor Q1, or as a so-called voltage stabilizing capacitor in time of rise of the clock signal input to the first clock terminal CK1. Therefore, the boosting operation of the node N1 in the selective period can be performed only by the capacitance of the gate and the channel of the transistor Q1, and the capacitance element C1 does not need to be arranged in the unit shift register SR if the voltage rise of the node N1 in the non-selective period is small.

An example in which the gate line driving circuit 30 is configured by the bi-directional unit shift register SR as in FIG. 2, and driven by the two phase clock signals has been described in the above description, but the application of the present invention is not limited thereto. The present invention is also applicable to when configuring the gate line driving circuit 30 as in FIG. 12, and driving the same by three phase clock signals.

In this case, the clock signal different from the first clock terminal CK1 of the stage adjacent before and after is input to the clock terminal CK1 of each unit shift register SR. In each unit shift register SR, the clock signal of the phase different from the first clock terminal CK1 is input to the second clock terminal CK2. The order the clock signals CLK1, CLK2, and CLK3 become H level can be changed according to the shift direction of the signal by change in connection of clock signal wiring or by change in program of the clock generator 31. For example, in the configuration of FIG. 12, the clock signals become H level in the order of CLK1, CLK2, CLK3, CLK1, . . . , in the forward shift and become H level in the order of CLK3, CLK2, CLK1, CLK3, . . . , in the reverse shift.

The operation of each unit shift register SR of when the gate line driving circuit 30 is driven by three phase clock signals is the same as when driven by the two phase clock signals, and thus the description thereof will be omitted herein.

### Second Embodiment

In the bi-directional unit shift register SR configured with a-Si TFT of first embodiment (FIG. 8), since the clock signal /CLK is input to the gate of the transistor Q2, the arise of problem in that the threshold voltage of the transistor Q2 shifts and the driving ability gradually lowers (fourth problem) is suppressed. However, the shift in the threshold voltage of the transistor Q2 is not completely eliminated, and the threshold voltage gradually shifts as the clock signal /CLK repeatedly becomes H level, and the above problem may ultimately arise. In second embodiment, the unit shift register SR capable of further suppressing such problem is proposed.

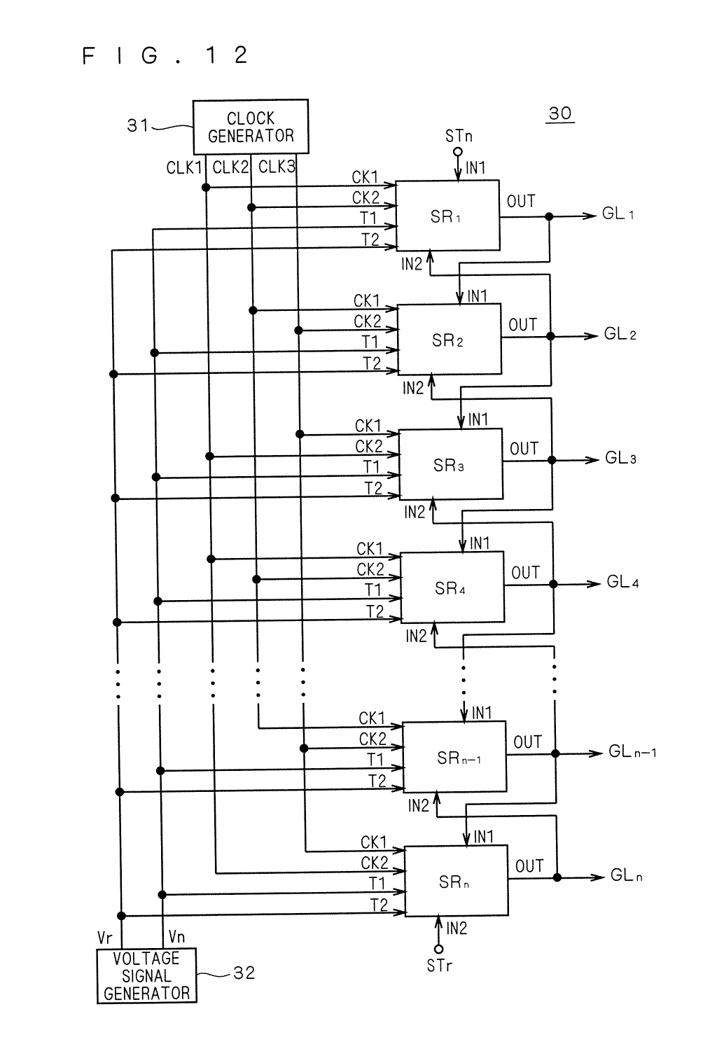

FIG. 13 is a circuit diagram showing the configuration of the unit shift register according to second embodiment. As shown in the figure, the source of the transistor Q2 is connected to the first clock terminal CK1. That is, one main electrode (drain) of the transistor Q2 is connected to the output terminal OUT, and the other main electrode (source) is provided with the clock signal having a phase different from the clock signal /CLK input to the control electrode (gate).

According to such configuration, when the clock signal /CLK input to the gate of the transistor Q2 becomes L level and the transistor Q2 is turned OFF, the clock signal CLK input to the source becomes H level, and thus becomes a state equivalent to when the gate of the transistor Q2 is negatively biased with respect to the source. Thus, the threshold voltage shifted in the positive direction returns to the negative direction and is restored, and thus the lowering in the driving ability of the transistor Q2 is alleviated further from first embodiment, and the operating life of the circuit is lengthened.

In the present embodiment, the signal input to the source of the transistor Q2 may be any signal as long as it is the clock signal having a phase different from that input to the gate. The above description is made on the assumption that the gate line driving circuit 30 configured by the unit shift register SR is driven with two phase clock signal, but the present embodiment is also applicable to the unit shift register SR of the gate line driving circuit 30 driven with three phase clock signal as shown in FIG. 12. In this case, one of the two clock signals other than that input to the gate of the transistor Q2 may be input to the transistor Q2.

The above description is made on the assumption that the unit shift register SR is configured by a-Si TFT, but the application of the present embodiment is not limited thereto. That is, the present embodiment is widely used on the unit shift register SR configured by the transistor in which the shift of the threshold voltage occurs similar to a-Si TFT such as organic TFT, in which case as well, effects similar to the above are also obtained.

### Third Embodiment

As described using FIG. 10, when the gate-source voltage V_{GS}(Q5) of the transistor Q5 exceeds the threshold voltage Vth(Q5) in time of rise of the output signal (Gk) in the bi-directional unit shift register SR of first embodiment, the current (I(Q5)) flows from the node N1 to the output terminal OUT via the transistor Q5. As described above, since only slight amount of current normally flows, and thus does not lower the level of the node N1 to an extent of influencing the driving ability of the transistor Q1, the current (I(Q5)) flowing through the transistor Q5 increases and the driving ability of the transistor Q1 may lower when the output load capacity is large and the rise of output signal is slow. The bi-directional unit shift register SR for resolving such problem is proposed in third embodiment.

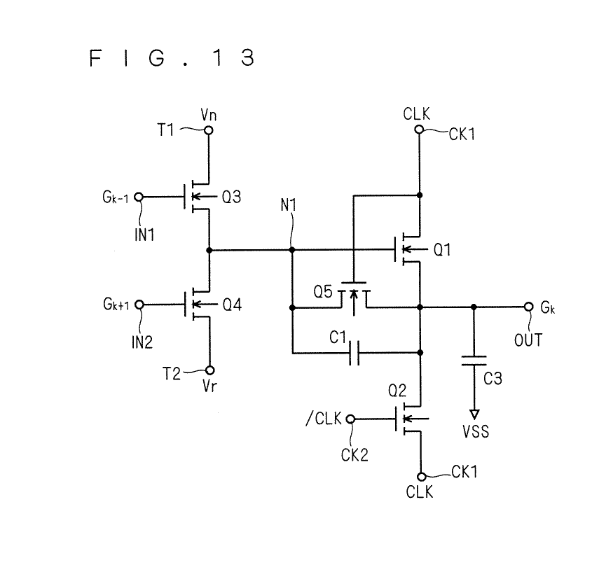

FIG. 14 is a circuit diagram of the bi-directional unit shift register SR according to third embodiment. In the unit shift register SR shown in FIG. 14, the gate of the transistor Q5 and the first clock terminal CK1 are not directly connected, and a level adjustment circuit 100 is interposed in between. The level adjustment circuit 100 lowers the clock signal input to the first clock terminal CK1 by a predetermined value from H level and provides the signal to the gate of the transistor Q5.

In the example of FIG. 14, the level adjustment circuit 100 is configured by transistors Q21 and Q22. If the node connected with the gate of the transistor Q5 is defined as node N5 (second node), the transistor Q21 is connected between the node N5 and the first clock terminal CK1, and the gate thereof is connected to the first clock terminal CK1 (i.e., transistor Q21 is diode connected so that a direction from the first clock terminal CK1 to the node N5 is a forward direction (charging direction)). The transistor Q22 is connected between the node N5 and the first power supply terminal S1, and the gate thereof is connected to the second clock terminal CK2.

The operation of the unit shift register SR of third embodiment will now be described. The relevant unit shift register SR is driven by two phase clock signals CLK, /CLK, where the clock signal CLK1 is assumed to be input to the first clock terminal CK1 and the clock signal /CLK to be input to the second clock terminal CK2.

The operation of the unit shift register SR of FIG. 14 is basically the same as the circuit (FIG. 8) of first embodiment, but the clock signal CLK is provided to the gate of the transistor Q5 via the level adjustment circuit 100. When the clock signal CLK becomes H level, a signal in which the H level of the clock signal CLK is reduced by threshold voltage of the transistor Q21 is provided to the gate of the transistor Q5 (in this case, clock signal /CLK is L level, and transistor Q22 is turned OFF).

As a result, the gate-source voltage (V_{GS}(Q5)) of the transistor Q5 becomes smaller in time of rise of the output signal (Gₖ), and thus is less likely to exceed the threshold voltage (Vth(Q5)). Therefore, even if the output load capacity is large and the rise of the output signal is slow, the current (I(Q5)) that flows to the transistor Q5 at the relevant point can be small or 0, thereby suppressing lowering in the driving ability of the transistor Q1.

Since the transistor Q21 functions as a diode with the first clock terminal CK1 as anode and the node N5 as cathode, when the clock signal CLK returns to L level, the node N5 cannot be discharged in the transistor Q21, but the node N5 is discharged through the transistor Q22 and becomes L level since the clock signal /CLK becomes H level. As a result, the transistor Q5 operates substantially the same as first embodiment.

Although not shown, the level adjustment circuit 100 is applicable to the unit shift register SR of second embodiment (FIG. 13).

### Fourth Embodiment

A variant of the level adjustment circuit 100 described in third embodiment will be described in fourth embodiment.

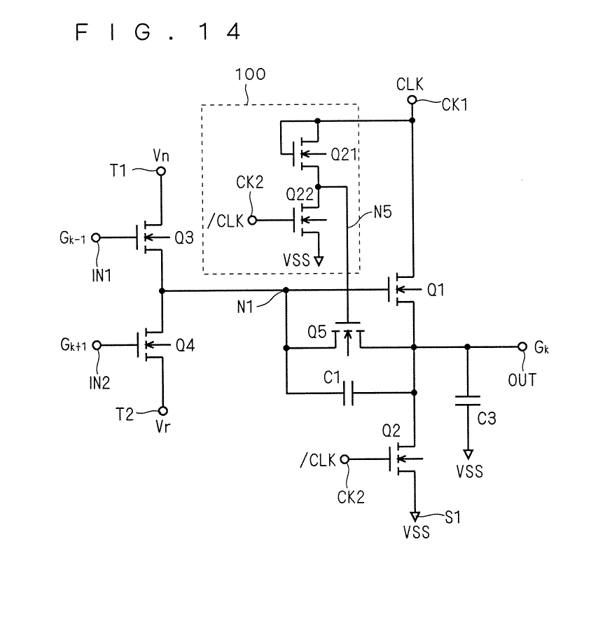

For example, if the current flowing to the transistor Q5 in time of rise of the output signal Gₖ of the unit shift register SR cannot be sufficiently suppressed even by using the level adjustment circuit 100 of FIG. 14, a level adjustment circuit 100 in which two transistors Q21 and Q23 both diode connected between the node N5 and the first clock terminal CK1 are connected in series as in FIG. 15 may be used. Compared to the level adjustment circuit 100 of FIG. 14, the H level of the signal provided to the gate of the transistor Q5 becomes smaller by the amount of threshold voltage of the transistor Q23, and thus is effective in further enhancing the effect of suppressing the current flowing to the transistor Q5.

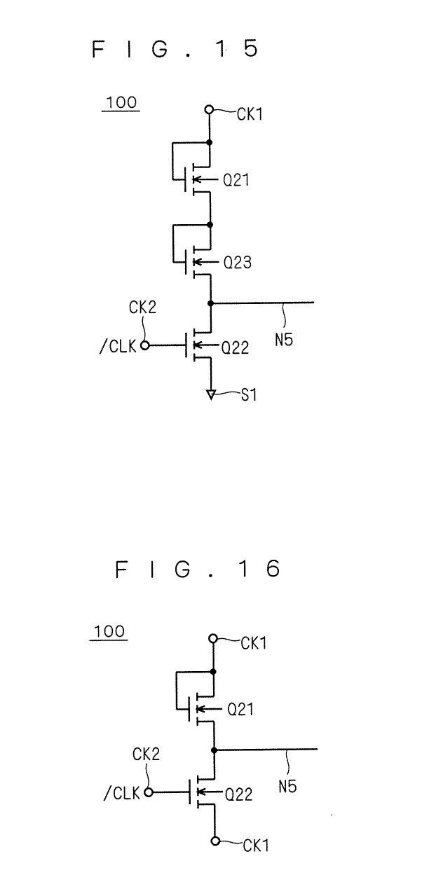

The source of the transistor Q22 is connected to the first power supply terminal S1 in FIG. 14, but may be connected to the first clock terminal CK1 as in FIG. 16. In this case, when the clock signal /CLK becomes L level and the transistor Q22 is turned OFF, the clock signal CLK input to the source becomes H level, and thus obtains a state equivalent to when the gate of the transistor Q22 is negatively biased with respect to the source. The threshold voltage of the transistor Q22 shifted to the positive direction returns to the negative direction and is restored, thereby obtaining the advantage of lengthening the operating life of the circuit. The level adjustment circuit 100 of FIG. 16 is effective for the unit shift register SR configured by transistors in which shift of the threshold voltage occurs similar to a-Si TFT such as organic TFT.

In the example of FIG. 16, the signal input to the source of the transistor Q22 may be arbitrary as long as it is the clock signal having a phase different from that input to the gate. Therefore, when the gate line driving circuit 30 is driven with the three phase clock signals as in FIG. 12, one of the two clock signals other than that input to the gate of the transistor Q22 may be input to the source of the transistor Q22.

In the unit shift register SR of FIG. 14, when the gate width of the transistor Q5 is large and the gate capacity thereof is considerably large with respect to parasitic capacity (not shown) attached to the node N5, it is considered that the level of the node N5 may rise by the coupling via overlapping capacity between the gate and the drain of the transistor Q5 in time of rise of the output signal Gₖ. If the rise in level of the node N5 is large, the transistor Q5 is turned ON while the output signal Gₖ is at H level, and the level of the node N1 lowers.

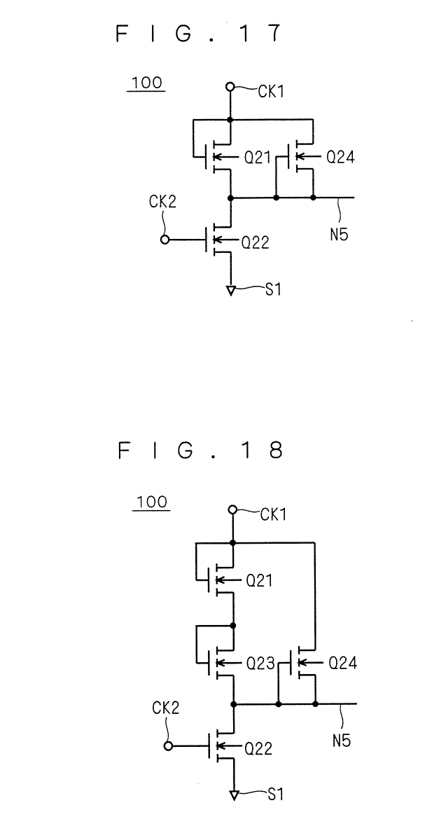

Therefore, a transistor Q24 (unidirectional switching element) diode connected between the node N5 and the first clock terminal CK1 so that the direction from the node N5 to the first clock terminal CK1 is the forward direction (discharging direction) may be arranged in the level adjustment circuit 100 as shown in FIG. 17. The transistor Q24 flows current from the node N5 to the first clock terminal CK1 and clamps the level of the node N5 to the level of the VDD+Vth(Q24) when the level of the node N5 rises to higher than or equal to the sum of the H level (VDD) of the clock signal CLK and the threshold voltage (Vth(Q24)) of the transistor Q24. Therefore, the voltage between the gate and the source of the transistor Q5 becomes Vth(Q24) at maximum, and electrical conduction of the transistor Q5 in time of output of the output signal Gₖ is substantially suppressed, whereby lowering in the level of the node N1 is also suppressed.

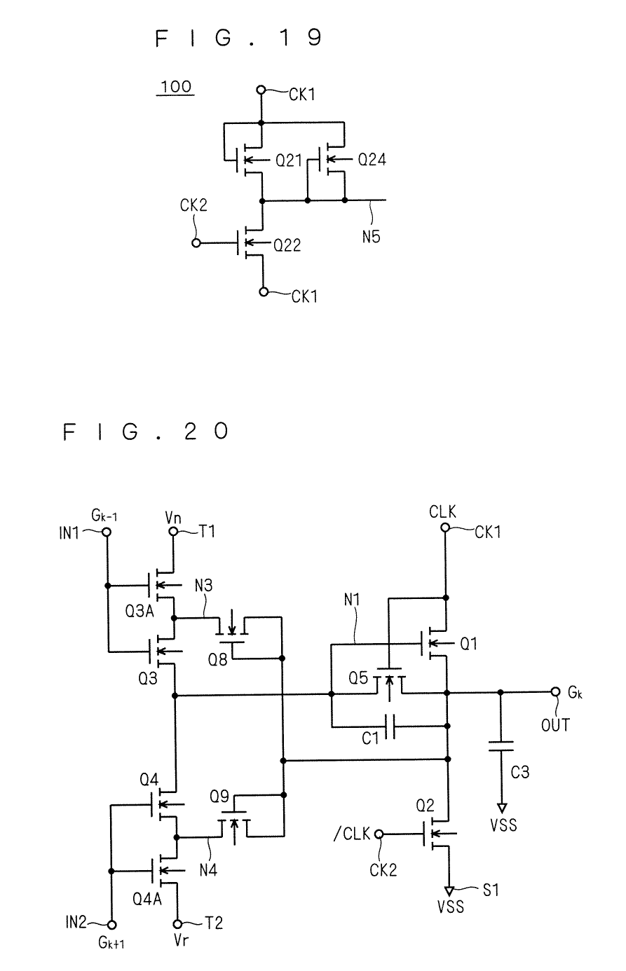

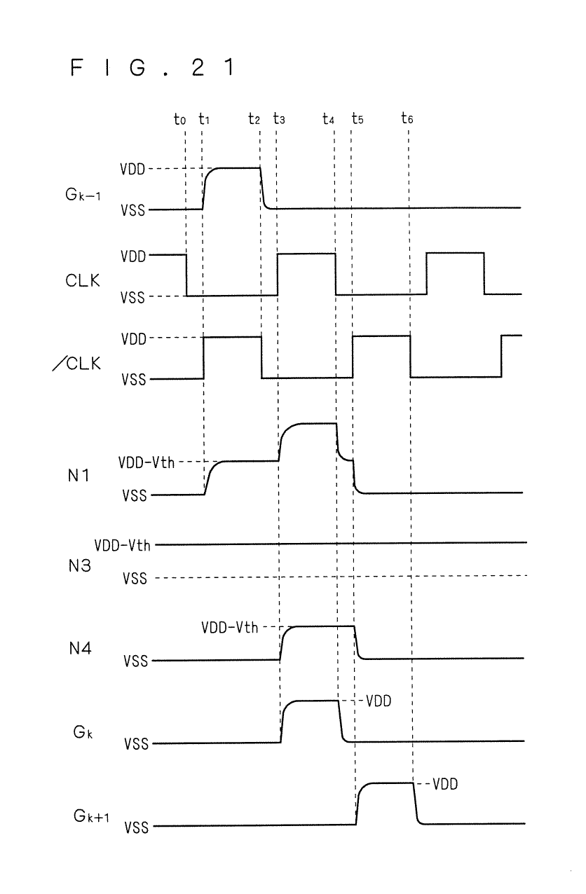

An example of arranging the transistor Q24 to the level adjustment circuit 100 shown in FIG. 14 has been shown in FIG. 17, but the transistor Q24 may be arranged in the level adjustment circuit 100 of FIG. 15 as shown in FIG. 18, or may be arranged in the level adjustment circuit 100 of FIG. 16 as shown in FIG. 19.

### Fifth Embodiment

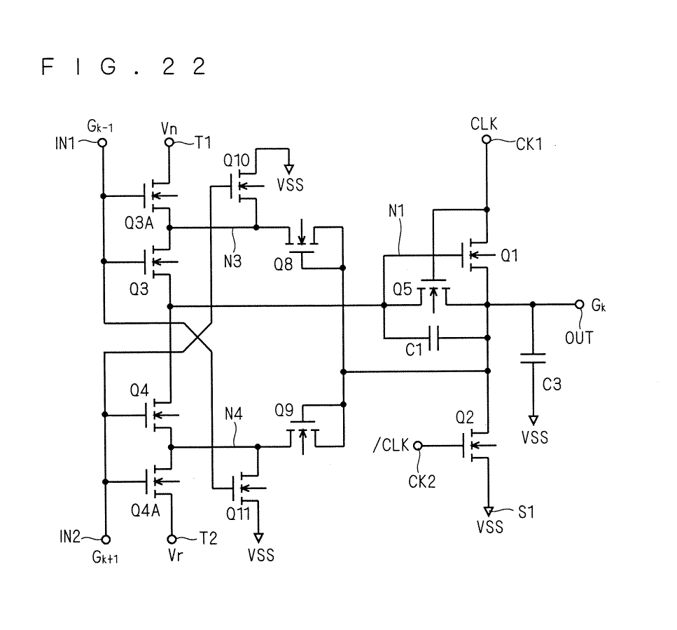

FIG. 20 is a circuit diagram of a bi-directional unit shift register SR according to fifth embodiment. As shown in the figure, the unit shift register SR has a configuration in which transistors Q3A, Q4A, Q8 and Q9 are further arranged in the unit shift register SR (FIG. 8) of first embodiment.

As shown in FIG. 20, the transistor Q3 is connected to the first voltage signal terminal T1 by way of the transistor Q3A, and the transistor Q4 is connected to the second voltage signal terminal T2 by way of the transistor Q4A. The gate of the transistor Q3A is connected to the first input terminal IN1 similar to the gate of the transistor Q3, and the gate of the transistor Q4A is connected to the gate of the transistor Q4. The connecting node (third node) between the transistor Q3 and the transistor Q3A is defined as node N3, and the connecting node (fourth node) between the transistor Q4 and the transistor Q4A is defined as node N4.

A transistor Q8 diode connected so that the direction from the output terminal OUT towards the node N3 is the forward direction (direction of flowing current) is connected between the output terminal OUT and the node N3. A transistor Q9 diode connected so that the direction from the output terminal OUT towards the node N4 is the forward direction is connected between the output terminal OUT and the node N4. The transistor Q8 flows current from the output terminal OUT towards the node N3 and charges the node N3 when the output terminal OUT is at H level (when activated). Similarly, the transistor Q9 flows current from the output terminal OUT towards the node N4 and charges the node N4 when the output terminal OUT is at H level. That is, the transistors Q8, Q9 function as charging circuits for charging the nodes N3, N4 with one direction from the output terminal OUT towards the nodes N3, N4 as the charging direction.

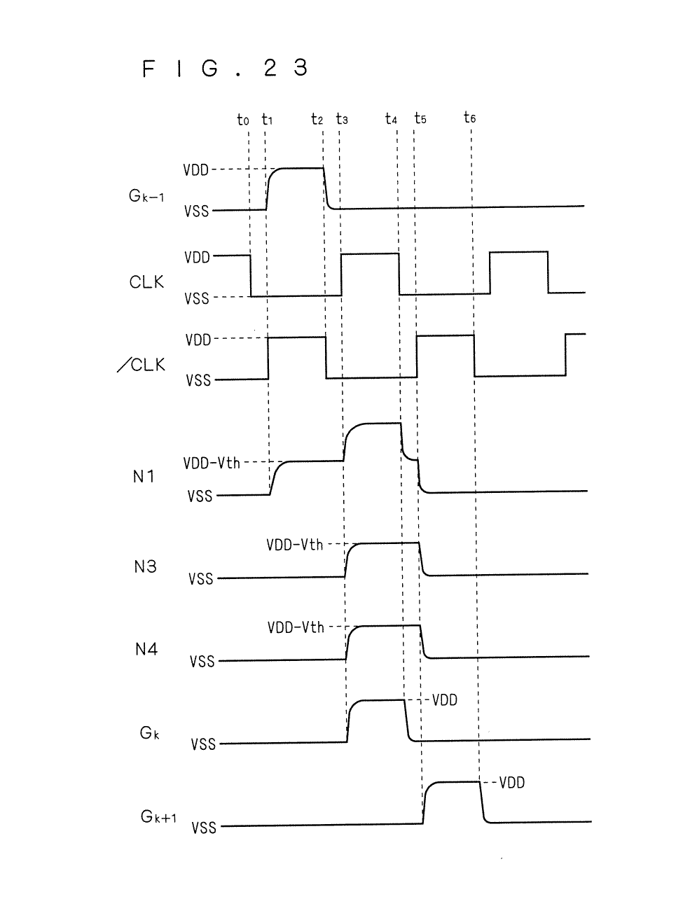

The operation of the bi-directional unit shift register SR of FIG. 20 will be described. FIG. 21 shows a timing chart showing the operation in time of forward shift of the unit shift register SR of FIG. 20.

The operation of unit shift register SRₖ of the k^{th} stage of when the gate line driving circuit 30 performs the operation of the forward shift will be described by way of example. That is, the first voltage signal Vn generated by the voltage signal generator 32 is at H level (VDD), and the second voltage signal Vr is at L level (VSS). The threshold voltages of each transistor configuring the unit shift register SR are assumed to be equal, and the value is assumed as Vth for the sake of convenience of explanation.

First, the reset state in which the node N1 is L level (VSS) is assumed as the initial state, the first clock terminal CK1 (clock signal CLK) is at H level, and the second clock terminal CK2 (clock signal/CLK), the first input terminal IN1 (output signal Gₖ₋₁ of previous stage), and the second input terminal IN2 (output signal Gₖ₊₁ of previous stage) are all at L level. Since all transistors Q1 to Q4, Q3A, Q4A are turned OFF, the node N1 and the output terminal OUT (output signal Gₖ) is at L level of floating state.

The clock signal CLK becomes L level at time t₀ from the above state, and thereafter, the clock signal /CLK becomes H level and the output signal Gₖ₋₁ (first control pulse STn serving as start pulse for the first stage) of the unit shift register SRₖ₋₁ of the previous stage becomes H level at time t₁, and the transistors Q3, Q3A are both turned ON. Since the first voltage signal Vn is H level, the node N1 becomes H level (VDD-Vth). That is, the relevant unit shift register SRₖ is at set state, and the transistor Q1 is turned ON. Although the node N3 is at H level (VDD-Vth), the current does not flow from the node N3 towards the output terminal OUT since the transistor Q8 functions as a diode having the direction from the output terminal OUT towards the node N3 as forward direction (charging direction). Since the clock signal /CLK is at H level, the transistor Q2 is turned ON, and the output terminal OUT is maintained at L level at low impedance.

Subsequently, the clock signal /CLK becomes L level at time t₂, and the output signal Gₖ₋₁ returns to L level. The transistors Q3, Q3A are then turned OFF, but the set state is maintained since the nodes N1, N3 are at H level of floating state. The transistor Q2 is also turned OFF.

When the clock signal CLK becomes H level at subsequent t₃, the transistor Q1 is turned ON and the transistor Q2 is turned OFF, and thus the level of the output terminal OUT following thereto rises. The level of the node N1 is boosted by a specific voltage. The level of the output signal Gₖ changes following the level of the first clock terminal CK1 since the driving ability of the transistor Q1 increases. The output signal Gₖ becomes H level (VDD) while the clock signal CLK is at H level. The operation of the transistor Q5 is as described using FIG. 10 in first embodiment, and thus the description thereof will be omitted herein.

In the conventional circuit of FIG. 3 and the unit shift register SR (FIG. 8) of first embodiment, there is a possibility that leakage current may be generated at the relevant transistor Q4 and the level of the node N1 may lower since high voltage is applied between the drain and the source of the transistor Q4 when the node N1 is boosted. The driving ability of the first transistor thus cannot be sufficiently ensured, and the falling speed of the output signal Gₖ may lower (second problem).

On the other hand, the diode connected transistor Q9 is turned ON and the level of the node N4 becomes VDD-Vth when the node N1 is boosted, that is, when the output terminal OUT becomes H level (VDD) in the unit shift register SR of FIG. 20. The transistor Q4 has the gate potential at VSS, and the source potential at VDD-Vth, and the gate is in a state negatively biased with respect to the source. Therefore, the leakage current between the drain and the source of the relevant transistor Q4 is sufficiently suppressed, and the lowering in the level of the node N1 is suppressed.

Therefore, when the clock signal CLK subsequently becomes L level at time t₄, the output signal Gₖ rapidly changes to L level following thereto, whereby the gate line GLₖ is discharged at high speed and becomes L level. Therefore, each pixel transistor is rapidly turned OFF, and occurrence of display failure caused by re-writing of data in the pixel to the data of the next line is suppressed.

The output signal Gₖ₊₁ of the next stage becomes H level at time t₅ at when the clock signal /CLK becomes H level. The transistors Q4, Q4A of the unit shift register SRₖ are turned ON, and the nodes N1, N4 become L level. That is, the unit shift register SR is in the reset state, and the transistor Q1 is turned OFF. Since the clock signal /CLK is at H level, the transistor Q2 is turned ON and the output terminal OUT is made to L level at low impedance.

Since the transistors Q4, Q4A are turned OFF when the output signal Gₖ₊₁ of the next stage returns to L level at time t₆, the node N1 and the node N4 become L level of floating state. This state continues until the signal is input to the first input terminal IN1 next, and the unit shift register SRₖ is maintained at reset state. In the meantime, the transistor Q5 is turned ON every time the clock signal CLK becomes H level, and thus the rise of node N1 caused by leakage current at the transistor Q3 is suppressed. That is, in the present embodiment, problem (first problem) of malfunction caused by rise in potential of the node N1 in the non-selective period is prevented.

The operation of the reverse shift will now be assumed. In this case, the first voltage signal Vn is at L level and the second voltage signal Vr is at H level, and thus when the node N1 is boosted, high voltage is applied between the drain and the source of the transistor Q3, and thus the leakage current becomes a concern in the conventional circuit of FIG. 3.

When the unit shift register SRₖ of FIG. 20 performs the operation of the reverse shift, on the other hand, the current flows to the node N3 via the transistor Q8 when the node N1 is boosted, and the level of the node N3 becomes VDD-Vth. The transistor Q3 has the gate potential at VSS and the source potential at VDD-Vth, and the gate is in a state negatively biased with respect to the source. Therefore, the leakage current between the drain and the source of the transistor Q3 is sufficiently suppressed, and lowering in the level of the node N1 is suppressed. That is, effects similar to the forward shift are obtained.

A configuration in which the transistors Q3A, Q4A, Q8, and Q9 according to the present embodiment are arranged in the bi-directional unit shift register (FIG. 8) of first embodiment has been shown in FIG. 20, but the present embodiment is also applicable to the bi-directional unit shift register SR of second and third embodiments (FIGS. 13, 14) and the like.

### Sixth Embodiment

The node N3 is continuously at the positive potential (VDD-Vth), as shown in FIG. 21, while the bi-directional unit shift register SR (FIG. 20) of the fifth embodiment is performing the operation of the forward shift. This means that gate-source and gate-drain of the transistor Q3A are negatively biased, which leads to a great shift in the negative direction of the threshold voltage of the transistor Q3A. When the shift to the negative direction of the threshold voltage advances, the transistor substantially becomes a normally ON type, where the current flows between the drain and the source even if the voltage between the gate and the source is 0V. When the transistor Q3 becomes normally ON, the following problems arise when the relevant unit shift register SR subsequently performs the operation of the reverse shift.

That is, in the unit shift register SR of the fifth embodiment, the current for charging the node N3 through the transistor Q8 when the output terminal OUT becomes H level (when node N1 is boosted) in the reverse shift in which the first voltage signal Vn is at L level (VSS). However, since the transistor Q4A is normally ON, the charges due to the current thereof flows out to the first input terminal IN1 through the transistor Q3A, and the power consumption increases. In addition, the effect of the fifth embodiment to suppress the leakage current of the transistor Q3 cannot be obtained since the node N3 cannot be sufficiently charged. The bi-directional unit shift register that solves such problem is thereby proposed in the sixth embodiment.

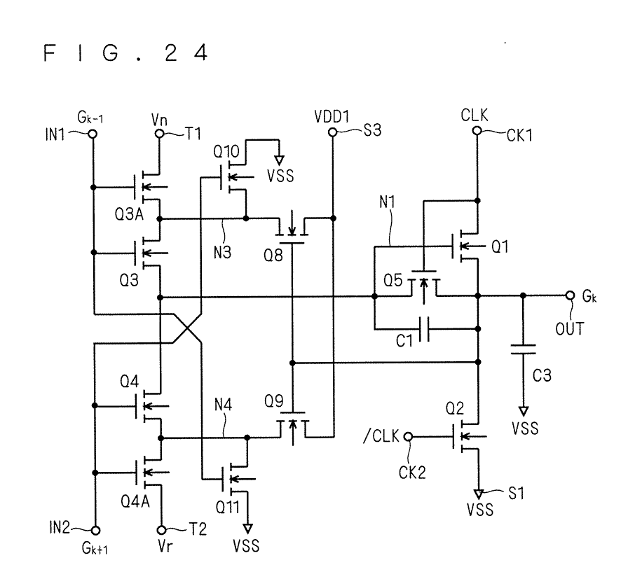

FIG. 22 is a circuit diagram showing the configuration of the bi-directional unit shift register according to the sixth embodiment. As shown in the figure, a transistor Q10, which gate is connected to the second input terminal IN2, is arranged between the node N3 and the first power supply terminal S1 (VSS), and a transistor Q11, which gate is connected to the first input terminal IN1, is arranged between the node N4 and the first power supply terminal S1 with respect to the unit shift register SR (FIG. 20) of the fifth embodiment. In other words, the transistor Q11 is a transistor for discharging the node N4 (fourth node) based on the signal (first input signal) input to the first input terminal IN1, and the transistor Q10 is a transistor for discharging the node N3 (third node) based on the signal (second input signal) input to the second input terminal IN2.

FIG. 23 is as timing chart showing the operation in time of the forward shift of the bi-directional unit shift register according to the sixth embodiment. The relevant operation is substantially the same as that shown in FIG. 21, and thus the detailed description will be omitted, and only the characteristic features of the present embodiment will be described.

In the present embodiment, since the transistor Q10 is turned ON when the output signal Gₖ₊₁ of the next stage becomes H level at time t₅, the node N3 is discharged to L level (VSS) at the relevant timing. When the output signal Gₖ₊₁ of the next stage returns to L level at the subsequent time t₆, the transistor Q10 is turned OFF, but the node N3 is in the floating state, and the node N3 is maintained at L level until the output signal Gₖ₋₁ of the previous stage becomes H level the next time. That is, the node N3 is charged only for about one horizontal period of time t₃ to t₅, and the transistor Q3A only has gate-source and gate-drain negatively biased during the relevant period, as shown in FIG. 23. Therefore, the threshold voltage of the transistor Q3A barely shifts, and the above problem is prevented.

In the operation of the reverse shift, the transistor Q11 is turned ON and the node N4 is discharged to L level (VSS) when the output signal Gₖ₋₁ of the previous stage is at H level. As a result, gate-source and gate-drain of the transistor Q4A are prevented from continuously being negatively biased, and the threshold voltage of the transistor Q4 barely shifts. That is, effects similar to the forward shift are obtained.

### Seventh Embodiment

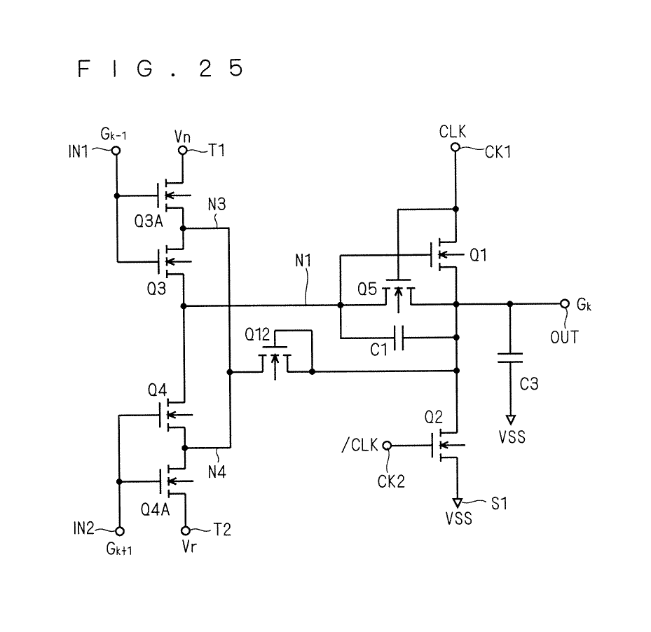

FIG. 24 is a circuit diagram of a bi-directional unit shift register SR according to the seventh embodiment. In the sixth embodiment, the drains of the transistors Q8, Q9 configuring the charging circuits for charging the nodes N3, N4 are connected to the output terminal OUT, and the relevant transistors Q8, Q9 function as diodes. In the present embodiment, however, the drains of the transistors Q8, Q9 are connected to a third power supply terminal S3 to be supplied with a predetermined high potential side power supply potential VDD1.

The operation of the unit shift register SR of FIG. 24 is basically the same as the sixth embodiment, and similar effects are obtained. However, the present embodiment differs from the sixth embodiment in that the supply source of the charges for charging the node N3 and the node N4 is not the output signal that appears at the output terminal OUT, but is the power supply for supplying the high potential side power supply potential VDD1.

According to the present embodiment, the charging speed of the gate line increases since the load capacity of the output terminal OUT is reduced compared to the unit shift register SR of sixth embodiment. Therefore, high speed operation is achieved. The present embodiment has been described as a variant of sixth embodiment, but is applicable to the unit shift register SR (FIG. 20) of fifth embodiment.

### Eighth Embodiment

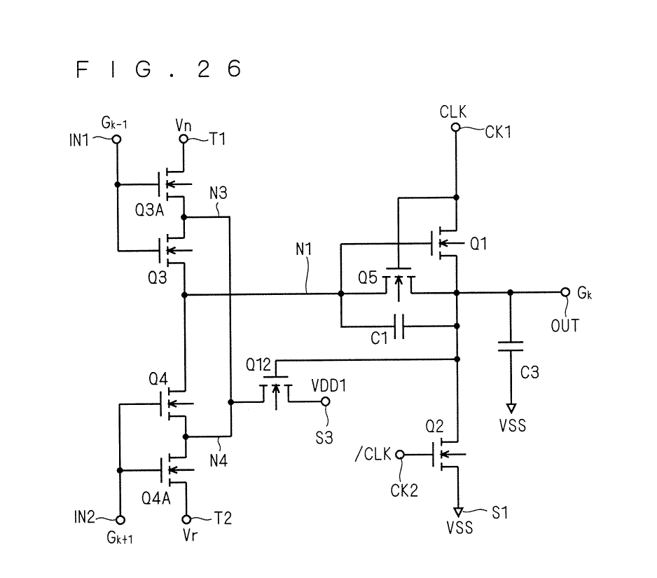

FIG. 25 is a circuit diagram of a bi-directional unit shift register according to eighth embodiment. As apparent from FIG. 23, the node N3 and the node N4 are at the same potential with respect to each other in sixth embodiment. In the present embodiment, the transistors Q10, Q11 are omitted, and the node N3 and the node N4 are connected to each other with respect to the circuit (FIG. 22) of the unit shift register SR of sixth embodiment. In addition, the transistors Q8, Q9 configuring the charging circuit for charging the nodes N3, N4 are replaced by one transistor Q12. The transistor Q12 is connected between the output terminal OUT and the nodes N3, N4, and diode connected so that the direction from the output terminal OUT towards the nodes N3, N4 is the forward direction (charging direction).

In the present embodiment, the nodes N3, N4 are at the same potential with respect to each other. For example, in forward shift (first voltage signal Vn is at H level, second voltage signal Vr is at L level), the nodes N3, N4 are both charged when the output signal Gₖ₋₁ of the previous stage input to the first input terminal IN1 becomes H level, and discharged when the output signal Gₖ₊₁ of the next stage input to the second input terminal IN2 becomes H level. In reverse shift (first voltage signal Vn is at L level, second voltage signal Vr is at H level), the nodes N3, N4 are both charged when the output signal Gₖ₊₁ of the next stage input to the second input terminal IN2 becomes H level, and discharged when the output signal Gₖ₋₁ of the previous stage input to the first input terminal IN1 becomes H level. That is, the voltage waveform of the nodes N3, N4 becomes the same as in sixth embodiment (FIG. 23).

Therefore, according to the present embodiment, effects similar to sixth embodiment are obtained. Effects are obtained without using transistors Q10, Q11 with respect to sixth embodiment, and furthermore, the number of transistors can be reduced since the transistors Q8, Q9 are replaced by one transistor Q12, thereby contributing to saving the forming area of the unit shift register SR.

### Ninth Embodiment

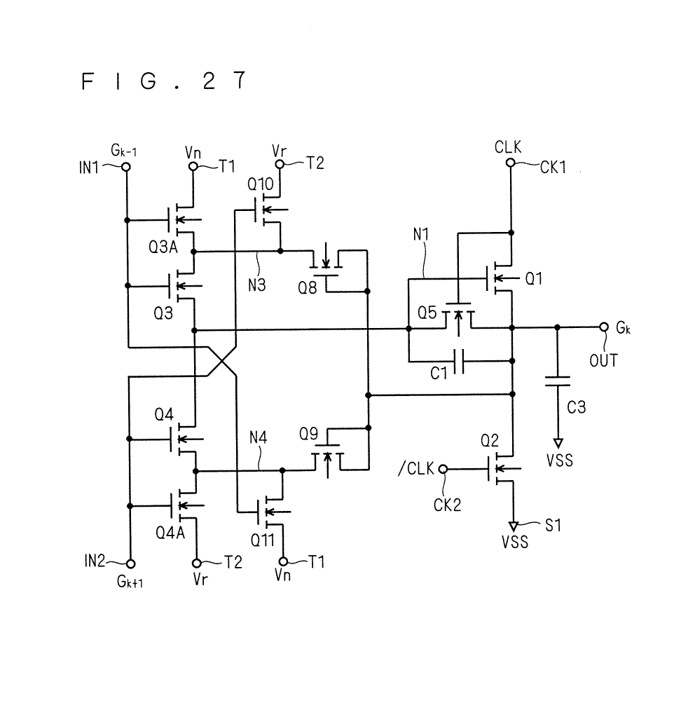

FIG. 26 is a circuit diagram of a bi-directional unit shift register SR according to eighth embodiment. In the present embodiment, seventh embodiment is applied to eighth embodiment, and the drain of the transistor Q12 is connected to a third power supply terminal S3 supplied with a predetermined high potential side power supply potential VDD1. The operation of the unit shift register SR of FIG. 26 is the same as eighth embodiment besides the fact that the supply source of charges for charging the nodes N3, N4 is the power supply for supplying high potential side power supply potential VDD1, and similar effects are obtained.

According to the present embodiment, the charging speed of the gate line increases since the load capacity of the output terminal OUT is reduced compared to the unit shift register SR of eighth embodiment. Therefore, higher speed operation is achieved.

### Tenth Embodiment

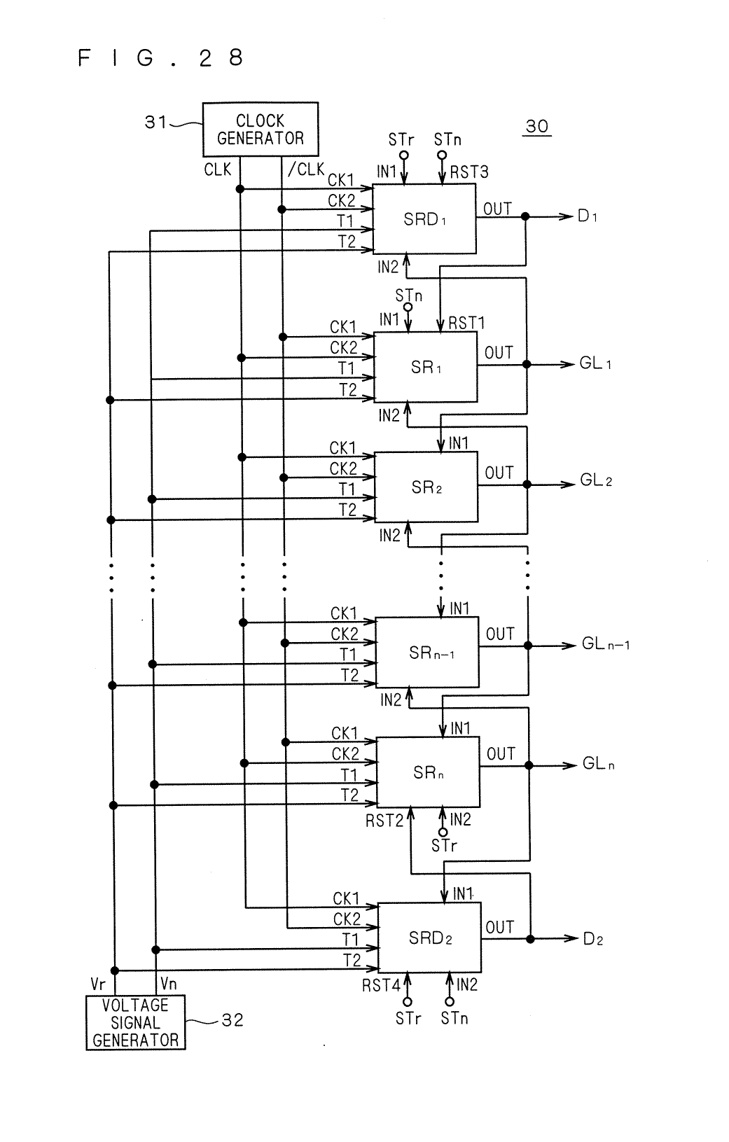

FIG. 27 is a circuit diagram showing a configuration of the bi-directional unit shift register SR according to tenth embodiment. The sources of the transistors Q10, Q11 are connected to the first power supply terminal S1 supplied with low potential side power supply potential VSS in sixth embodiment, whereas the source of the transistor Q10 is connected to the second voltage signal terminal T2 provided with the second voltage signal Vr and the source of the transistor Q11 is connected to the first voltage signal terminal T1 provided with the first voltage signal Vn as shown in FIG. 27.

The operation of the unit shift register SR of FIG. 27 is basically the same as sixth embodiment. That is, in the operation of forward shift, the transistor Q10 discharges the node N3 similar to sixth embodiment since the second voltage signal Vr is at L level. In the operation of the reverse shift, the transistor Q11 discharges the node N4 similar to sixth embodiment since the first voltage signal Vn is at L level.

Therefore, effects similar to sixth embodiment are obtained in the present embodiment. In other words, effects of sixth embodiment are obtained with the configuration of FIG. 22 and with the configuration of FIG. 27, and thus the degree of freedom of design of the layout of the circuit increases thereby contributing to reduction in the circuit occupying area.

The present embodiment is also applicable to the unit shift register SR (FIG. 24) of seventh embodiment.

### Eleventh Embodiment

The bi-directional unit shift register SR according to the present invention described above configures the gate line driving circuit 30 by being cascade connected as in FIG. 7 and FIG. 12. However, in performing forward shift in the gate line driving circuit 30 of FIG. 7 or FIG. 12, the first control pulse STn serving as the start pulse is input to the first input terminal IN1 of the leading stage (unit shift register SR₁), and thereafter, the second control pulse STr serving as the end pulse must be input to the second input terminal IN2 of the final stage (unit shift register SRₙ) similar to the prior art of FIG. 4. In performing reverse shift, the second control pulse STr serving as the start pulse is input to the second input terminal IN2 of the final stage, and thereafter, the first control pulse STₙ serving as the end pulse must be input to the first input terminal IN1 of the leading stage similar to the prior art of FIG. 5.

In other words, two types of control pulses of start pulse and end pulse are necessary in the operation of the gate line driving circuit 30 of FIG. 7 and FIG. 12, similar to the prior art. Thus, the drive controlling device for controlling the operation of the gate line driving circuit 30, that is to be adopted, is such mounted with the output circuit of the end pulse in addition to the output circuit of the start pulse, which increases the cost (third problem). Thus, the bi-directional shift register operable only with the start pulse is proposed in the eleventh embodiment.

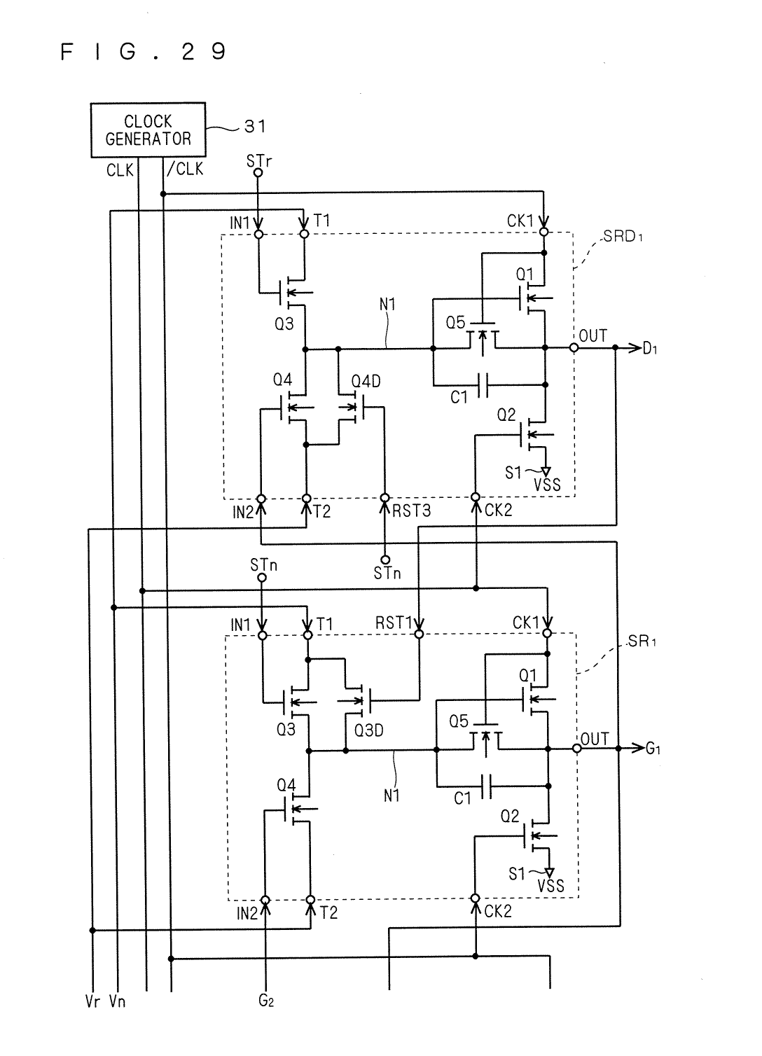

FIGS. 28 to 30 are views showing the configuration of the gate line driving circuit 30 according to the eleventh embodiment. As shown in the block diagram of FIG. 28, the gate line driving circuit 30 according to the present embodiment is also configured by a bi-directional shift register comprising a plurality of stages, but a first dummy shift register SRD₁ acting as the first dummy stage is arranged in a further previous stage of the unit shift register SR₁ of the leading stage for driving the gate line GL₁ in the plurality of stages, and a second dummy shift register SRD₂ serving as the second dummy stage is arranged on the further next stage of the unit shift register SRₙ of the final stage for driving the gate line GLₙ. That is, the gate line driving circuit 30 comprises a plurality of stages including the first dummy stage at the beginning and the second dummy stage at the end. The capacitive element having the capacitance value same as the load capacitor of the unit shift registers SR₁ to SRₙ is arranged as a load capacitor C3 in between a constant potential source (e.g., VSS) at the output nodes of the first and second dummy shift registers SRD₁, SRD₂.

As shown in FIG. 28, the first control pulse STn is input to the first input terminal IN1 of the unit shift register SR₁ of the leading stage (excluding the first dummy shift register SRD₁ which is the first dummy stage), and the output signal of the previous stage is input to the first input terminal IN1 of the subsequent stages (unit shift register SR2 to second dummy shift register SRD₂). The second control pulse STr is input to the first input terminal IN1 of the first dummy shift register SRD₁.

The second control pulse STr is input to the second input terminal IN2 of the final stage (excluding the second dummy shift register SRD₂ which is the second dummy stage), and the output signal of the next stage is input to the second input terminal IN2 of the previous stages (unit shift register SRₙ₋₁ to first dummy shift register SRD₁). The first control pulse STn is input to the second input terminal IN2 of the second dummy shift register SRD₂.

In the present embodiment, the unit shift register SR₁ of the leading stage, the unit shift register SRₙ of the final stage, the first dummy shift register SRD₁, and the second dummy shift register SRD₂ each includes predetermined reset terminals RST1, RST2, RST3, RST4. As in FIG. 28, the output signal D₁ of the first dummy shift register SRD₁ is input to the reset terminal RST1 of the unit shift register SR₁, the output signal D₂ of the second dummy shift register SRD₂ is input to the reset terminal RST2 of the unit shift register SRₙ, the first control pulse STn is input to the reset terminal RST3 of the first dummy shift register SRD₁, and the second control pulse STr is input to the reset terminal RST4 of the second dummy shift register SRD₂. The unit shift register SR₁, the unit shift register SRₙ, the first dummy shift register SRD₁, and the second dummy shift register SRD₂ are configured so as to be in the reset state (state in which node N1 is at L level) when signals are input to the reset terminals RST1, RST2, RST3 and RST4 (details to be hereinafter described).

In the following description, each stage of each bi-directional shift register configuring the gate line driving circuit 30 is assumed to have the configuration of the bi-directional unit shift register SR (FIG. 8) of the first embodiment. The unit shift register SR₁ of the leading stage, the unit shift register SRₙ of the final stage, the first dummy shift register SRD₁, and the second dummy shift register SRD₂ have a configuration different from the other stages as is described above, but all have the configuration of the bi-directional unit shift register SR of the first embodiment.

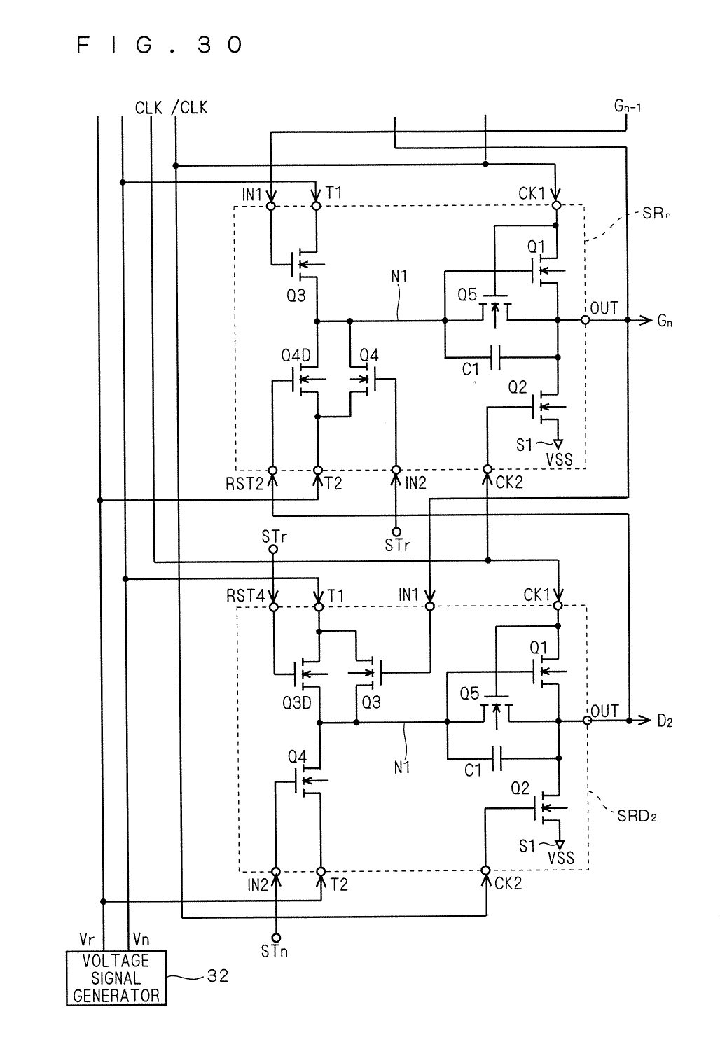

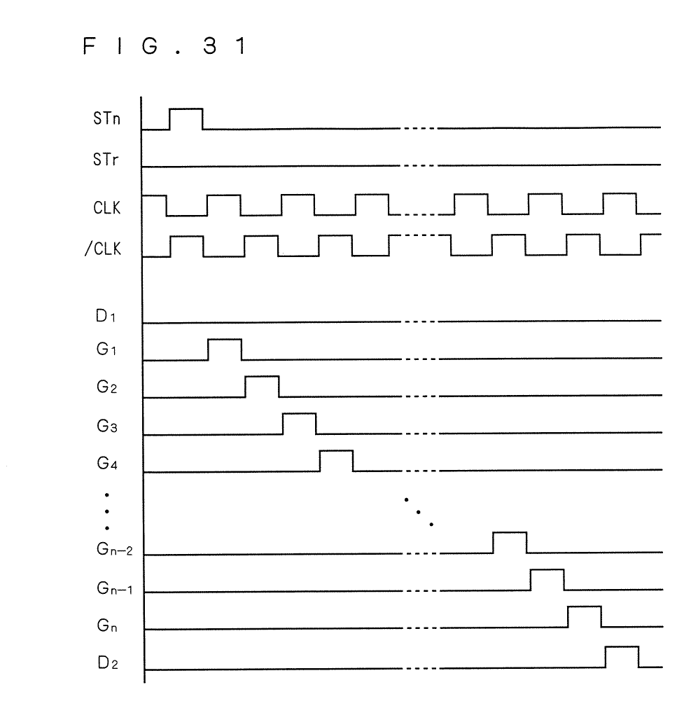

FIG. 29 is a specific circuit diagram of the first dummy shift register SRD₁ and the unit shift register SR₁ in the gate line driving circuit 30 of the present embodiment, and FIG. 30 is a specific circuit diagram of the unit shift register SRₙ and the second dummy shift register SRD₂.

Focusing on the unit shift register SR₁ of FIG. 29, the relevant unit shift register SR₁ has the same configuration as in FIG. 8 besides the fact that the transistor Q3D is connected in parallel to the transistor Q3. The gate of the transistor Q3D is connected to the reset terminal RST1.

Similarly, the first dummy shift register SRD₁ has the same configuration as in FIG. 8 besides the fact that the transistor Q4D is connected in parallel to the transistor Q4. The gate of the transistor Q4D is connected to the reset terminal RST3. The transistor Q4D is not essential in the operation of the first dummy shift register SRD₁, and is arranged so that the node N1 becomes the state of L level (reset state) at the initial stage of the operation. For example, if the transistor Q4D is not arranged, and the node N1 does not become L level at the initial stage in such state, the output signal D₁ of the first dummy shift register SRD₁ becomes H level, the transistor Q3D of the unit shift register SR₁ accordingly becomes turned ON, and the node N1 of the unit shift register SR₁ is charged, and thus the first frame is not performed with the normal operation. However, a dummy frame worth of one frame may be arranged prior to the normal operation if the transistor Q4D is not arranged since normal operation is performed from the next frame.

Focusing on the unit shift register SRₙ of FIG. 30, the relevant unit shift register SRₙ has the same configuration as in FIG. 8 (i.e., same circuit configuration as first dummy shift register SRD₁) besides the fact that the transistor Q4D is connected in parallel to the transistor Q4. The gate of the transistor Q4D is connected to the reset terminal RST2.

Similarly, the second dummy shift register SRD₂ has the same configuration as in FIG. 8 (i.e., same circuit configuration as unit shift register SR₁) besides the fact that the transistor Q3D is connected in parallel to the transistor Q3. The gate of the transistor Q3D is connected to the reset terminal RST4. The transistor Q3D is not essential in the operation of the second dummy shift register SRD₂, and is arranged so that the node N1 becomes the state of L level (reset state) at the initial stage of the operation. For example, if the transistor Q3D is not arranged, and the node N1 does not become L level at the initial stage in such state, the output signal D₂ of the second dummy shift register SRD₂ becomes H level, the transistor Q4D of the unit shift register SRₙ accordingly becomes turned ON, and the node N1 of the unit shift register SRₙ is charged, and thus the first frame is not performed with the normal operation. However, a dummy frame worth of one frame may be arranged prior to the normal operation if the transistor Q4D is not arranged since normal operation is performed from the next frame.

The operation of the gate line driving circuit 30 according to the present embodiment will now be described. First, the operation of forward shift will be described. In the forward shift, the first voltage signal Vn provided by the voltage signal generator 32 is set at H level, and the second voltage signal Vr is set at L level. That is, in this case, the transistor Q4D of the first dummy shift register SRD₁ and the transistor Q4D of the second dummy shift register SRD₂ operate to discharge the respective node N1. The unit shift registers SR₁ to SRₙ are assumed to be already in the reset state (state in which node N1 is at L level) for the sake of simplifying the explanation.

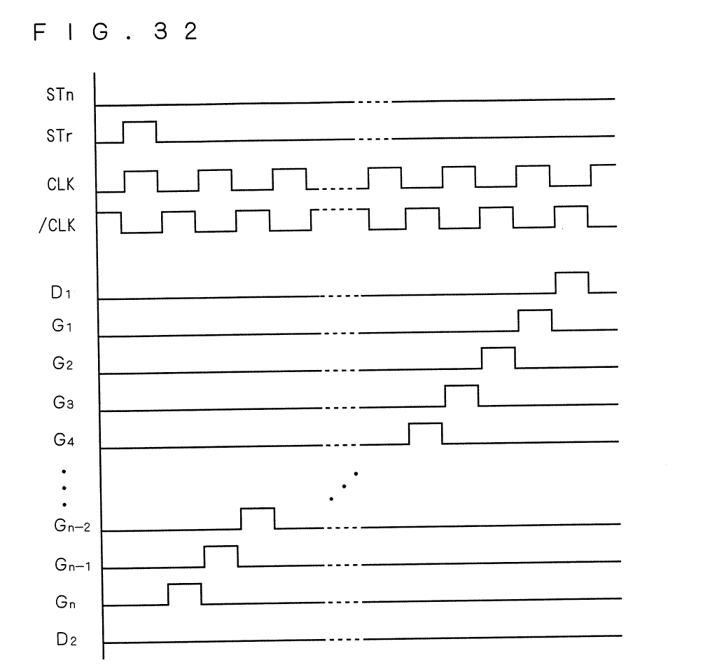

FIG. 31 is a timing chart showing the operation in forward shift of the gate line driving circuit 30 according to the present embodiment. As shown in FIG. 31, the first control pulse STn serving as the start pulse is input to the first input terminal IN1 of the unit shift register SR₁ of the leading stage at a predetermined timing in the forward shift. Thus, the unit shift register SR₁ becomes the set state (state in which node N1 is at H level). The second control pulse STr is not activated and maintained at L level.

The first control pulse STn (start pulse) is input to the reset terminal RST3 of the first dummy shift register SRD₁ and the second input terminal IN2 of the second dummy shift register SRD₂. In the first dummy shift register SRD₁, the transistor Q4 is turned ON, the node N1 becomes L level, and the state of the first dummy shift register SRD₁ becomes the reset state. Therefore, the output signal D₁ of the first dummy shift register SRD₁ becomes L level, and the transistor Q3D of the unit shift register SR₁ is turned OFF.

In the second dummy shift register SRD₂, the transistor Q4 is turned ON, the node N1 becomes L level, and the state of the second dummy shift register SRD₂ also becomes the reset state. Therefore, the output signal D₂ of the second dummy shift register SRD₂ becomes L level and the transistor Q4D of unit shift register SRₙ is turned OFF.

Subsequently, the signal is sequentially transmitted to the unit shift registers SR₁ to SRₙ and the second shift register SRD₂ as shown in FIG. 31 in synchronization with the clock signals CLK, /CLK according to the operation of forward shift similar to the first embodiment, and the output signals G₁, G₂, G₃, . . . , Gₙ, D₂ sequentially become H level.

As apparent from FIG. 31, the output signal D₂ of the second dummy shift register SRD₂ becomes H level immediately after the unit shift register SRₙ of the final stage outputs the output signal Gₙ. The output signal D₂ is input to the reset terminal RST2 of the unit shift register SRₙ, whereby the relevant transistor Q4D is turned ON and the relevant unit shift register SRₙ becomes the reset state. That is, the output signal D₂ functions as the end pulse of having the unit shift register SRₙ of the final stage in the reset state. The second dummy shift register SRD₂ becomes the reset state by the first control pulse STn serving as the start pulse of the next frame, and thus is similarly operable in the next frame.

Therefore, only the start pulse (first control pulse STn) is required in the operation of the forward shift of the gate line driving circuit 30 according to the present embodiment, and the end pulse is unnecessary.

The operation of reverse shift will now be described. In the reverse shift, the first voltage signal Vn is set at L level, and the second voltage signal Vr is set at H level. That is, in this case, the transistor Q3D of the unit shift register SR₁ and the transistor Q3D of the second dummy shift register SRD₂ operate to discharge the respective node N1. The unit shift registers SR₁ to SRₙ are assumed to be already in the reset state (state in which node N1 is at L level).

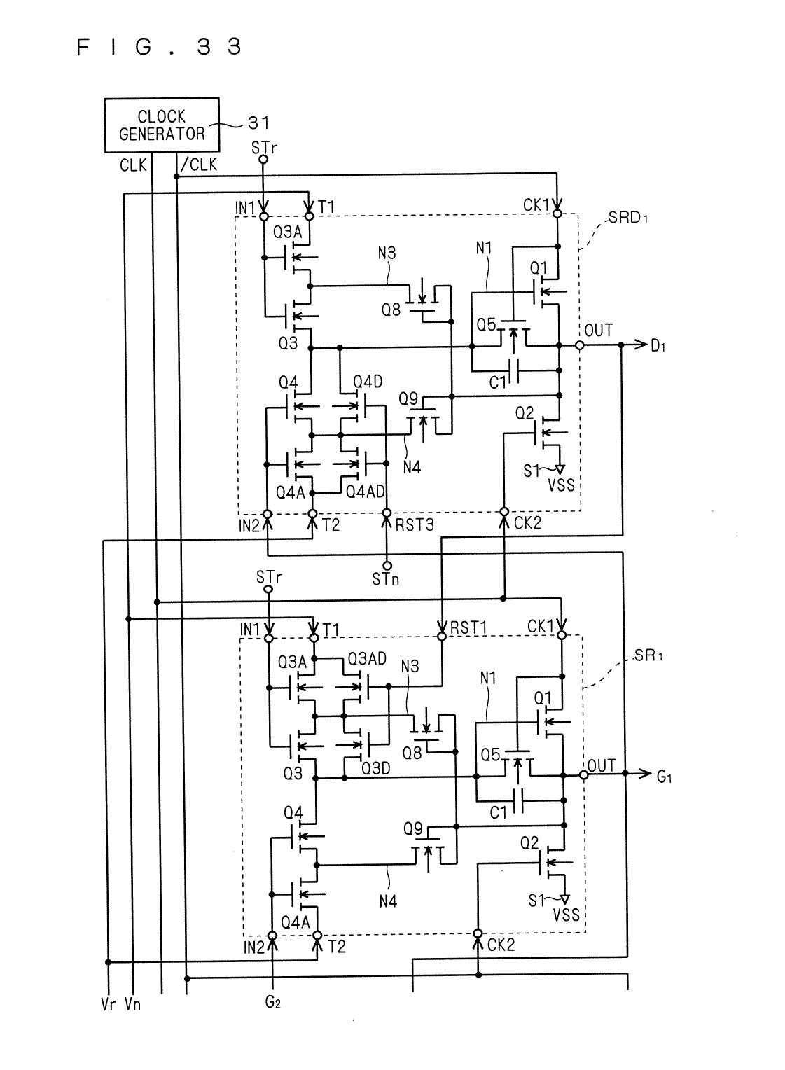

FIG. 32 is a timing chart showing the operation in reverse shift of the gate line driving circuit 30 according to the present embodiment. As shown in FIG. 32, the second control pulse STr serving as the start pulse is input to the second input terminal IN2 of the unit shift register SRₙ of the final stage at a predetermined timing in the reverse shift. Thus, the unit shift register SRₙ becomes the set state (state in which node N1 is at H level). The first control pulse STn is not activated and maintained at L level. The clock signals CLK, /CLK are changed with respect to each other by wiring connection or program change of the clock generator 31.

The second control pulse STr (start pulse) is input to the first input terminal IN1 of the first dummy shift register SRD₁ and the reset terminal RST4 of the second dummy shift register SRD₂. In the first dummy shift register SRD₁, the transistor Q3 is turned ON, and the node N1 becomes L level, and the state of the relevant first dummy shift register SRD₁ becomes the reset state. Therefore, the output signal D₁ of the first dummy shift register SRD₁ becomes L level, and the transistor Q3D of the unit shift register SR₁ is turned OFF.

In the second dummy shift register SRD₂, the transistor Q3D is turned ON, the node N1 becomes L level, and the state of the second dummy shift register SRD₂ also becomes the reset state. Therefore, the output signal D₂ of the second dummy shift register SRD₂ becomes at L level, and the transistor Q4D of the unit shift register SRₙ is turned OFF.

Subsequently, the signal is sequentially transmitted to the unit shift registers SR₁ to SRₙ and the first shift register SRD₁ as shown in FIG. 32 in synchronization with the clock signals CLK, /CLK according to the operation of reverse shift similar to the first embodiment, and the output signals Gₙ, Gₙ₋₁, Gₙ₋₂, . . . , G₁, D₁ sequentially become H level.

As apparent from FIG. 32, the output signal D₁ of the first dummy shift register SRD₁ becomes H level immediately after the unit shift register SR₁ of the leading stage outputs the output signal G₁. The output signal D₁ is input to the reset terminal RST1 of the unit shift register SR₁, whereby the relevant transistor Q3 is turned ON and the relevant unit shift register SR₁ becomes the reset state. That is, the output signal D₁ functions as the end pulse of having the unit shift register SR₁ of the leading stage in the reset state. The first dummy shift register SRD₁ becomes the reset state by the second control pulse STr serving as the start pulse of the next frame, and thus is similarly operable in the next frame.

Therefore, only the start pulse (second control pulse STr) is required in the operation of the reverse shift of the gate line driving circuit 30 according to the present embodiment, and the end pulse is unnecessary.

According to the present embodiment described above, the operation of the forward shift and the reverse shift can be performed with only the start pulse without using the end pulse in the bi-directional shift register. That is, the drive controlling device for controlling the operation of the gate line driving circuit 30 only needs to include the output circuit of the start pulse, and the problem of increase in cost (third problem) is resolved.

As described above, the transistor Q3D or the transistor Q4D arranged in the unit shift register SR₁, SRₙ, and the first and second dummy shift registers SRD₁, SRD₂ of the bi-directional shift register of the present embodiment function to discharge the corresponding nodes N1. When discharging the node N1 of each unit shift register SR, large driving ability (ability to flow current) is ensured compared to when charging the same, and high speed is not required. Thus, the size of the transistors Q3D, Q4D may be small compared to the transistors Q3, Q4, and may be about 1/10 and the like. Since the parasitic capacity of the node N1 becomes large when the size of the transistors Q3D, Q4D is large, the action of boosting the node N1 by the clock signal CLK or /CLK becomes small. The driving ability of the transistor Q1 becomes lower, and thus it is desirably small to a certain extent.

In the above description, each stage of the bi-directional shift register configures the unit shift register SR of the first embodiment, but the bi-directional unit shift register SR applied to the present embodiment may be any one of the bi-directional shift register SR of each embodiment.

In such case as well, the transistor Q3D parallel connected to the transistor Q3 is arranged in the unit shift register SR₁ of the leading stage, the transistor Q4D parallel connected to the transistor Q4 is arranged in the unit shift register SRₙ of the final stage, the transistor Q4D parallel connected to the transistor Q4 is arranged in the first dummy shift register SRD₁, and the transistor Q3D parallel connected to the transistor Q3 is arranged in the second dummy shift register SRD₂.

However, a transistor must be added in parallel to the transistors Q3A, Q4A when connecting the transistor Q3 to the first voltage signal terminal T1 by way of the transistor Q3A and connecting the transistor Q4 to the second voltage signal terminal T2 by way of the transistor Q4A as in the fifth embodiment (FIG. 20) and the sixth embodiment (FIG. 22).

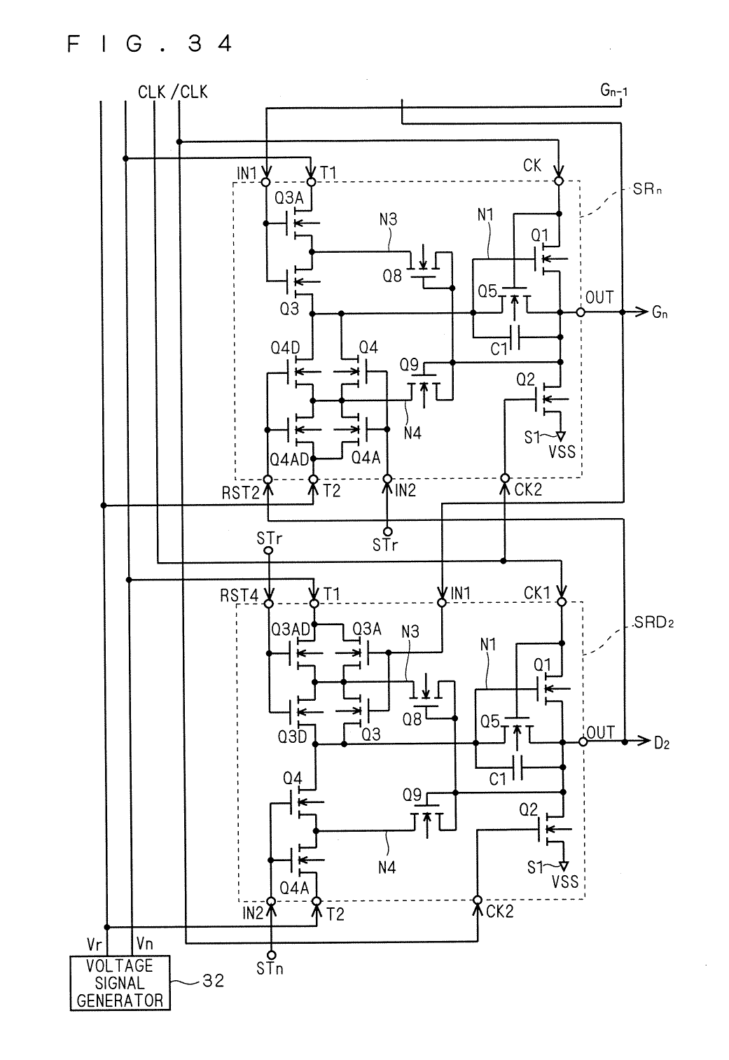

FIGS. 33 and 34 show an example in which the unit shift register SR of the fifth embodiment (FIG. 20) is applied to each stage of the gate line driving circuit 30 of the present embodiment. As shown in FIG. 33, the transistors Q3D, Q3AD are arranged in parallel to the transistors Q3, Q3A, respectively, in the unit shift register SR₁ of the leading stage, and the gates thereof are connected to the reset terminal RST1. The transistors Q4D, Q4AD are arranged in parallel to the transistors Q4, Q4A, respectively, in the first dummy shift register SRD₁, and the gates thereof are connected to the reset terminal RST3.

As shown in FIG. 34, the transistors Q4D, Q4AD are arranged in parallel to the transistors Q4, Q4A, respectively, in the unit shift register SR1 of the final stage, and the gates thereof are connected to the reset terminal RST2. The transistors Q3D, Q3AD are arranged in parallel to the transistors Q3, Q3A, respectively, in the second dummy shift register SRD₂, and the gates thereof are connected to the reset terminal RST4. According to such configuration, the operation of the forward shift and the reverse shift are possible only with the start pulse similar to the above.

In this case as well, the transistors Q3D, Q3AD, Q4D, Q4AD respectively function to discharge the level of the node N1, and thus the size thereof may be small compared to the transistors Q3, Q3A, Q4, Q4A, and may be about 1/10 and the like. Since the parasitic capacity of the node N1 becomes large when the size of the transistors Q3D, Q3AD, Q4D, Q4AD is large, the action of boosting the node N1 by the clock signal CLK or /CLK becomes small, thereby lowering the driving ability of the transistor Q1. Thus, it is desirable to be small to a certain extent.

While the invention has been shown and described in detail, the foregoing description is in all aspects illustrative and not restrictive. It is therefore understood that numerous modifications and variations can be devised without departing from the scope of the invention.

What is claimed is:

1. A shift register circuit comprising:
first and second input terminals, an output terminal and a first clock terminal;
a first transistor for providing a first clock signal input to said first clock terminal to said output terminal;
a second transistor for discharging said output terminal based on a second clock signal having a phase different from said first clock signal;
first and second voltage signal terminals input with first and second voltage signals complementary to each other;
a third transistor for providing said first voltage signal to a first node connected with a control electrode of said first transistor based on a first input signal input to said first input terminal;
a fourth transistor for providing said second voltage signal to said first node based on a second input signal input to said second input terminal; and
a switching circuit for electrically conducting said first node and said output terminal based on said first clock signal when said first node is discharged.

2. The shift register circuit according to claim 1, wherein a capacitive load is connected to said output terminal.

3. The shift register circuit according to claim 1, wherein
said switching circuit is a fifth transistor connected between said output terminal and said first node.

4. The shift register circuit according to claim 3, wherein
a control electrode of said fifth transistor is connected to said first clock terminal.

5. The shift register circuit according to claim 3, further comprising a level adjustment circuit for lowering an active level of said first clock signal by a predetermined amount and providing said first clock signal to a second node connected with the control electrode of said fifth transistor.

6. The shift register circuit according to claim 5, wherein
said level adjustment circuit includes,
one or more sixth transistor, connected between said first clock terminal and said second node, diode connected so that a direction from said first clock terminal to said second node is a charging direction; and
a seventh transistor for discharging said second node based on said second clock signal.

7. The shift register circuit according to claim 6, wherein
said seventh transistor includes one main electrode connected to said second node, a control electrode input with said second clock signal, and another main electrode provided with a third clock signal having a phase different from said second clock signal.

8. The shift register circuit according to claim 7, wherein said third clock signal is a signal same as said first clock signal.

9. The shift register circuit according to claim 5, wherein
said level adjustment circuit includes an unidirectional switching element, connected between said second node and said first clock terminal, having a direction from said second node to said first clock terminal as discharging direction.

10. The shift register circuit according to claim 9, wherein
said unidirectional switching element is a diode connected eighth transistor.

11. The shift register circuit according to claim 1, wherein
said second transistor includes one main electrode connected to said output terminal, a control electrode input with said second clock signal, and another main electrode provided with a third clock signal having a phase different from said second clock signal.

12. The shift register circuit according to claim 11, wherein
said third clock signal is a signal same as said first clock signal.

13. The shift register circuit according to claim 1, further comprising a capacitive element connected between said output terminal and said first node.

14. The shift register circuit according to claim 1, wherein
said third transistor is connected to said first voltage signal terminal by way of ninth transistor including a control electrode connected to the control electrode of said third transistor,
said fourth transistor is connected to said second voltage signal terminal by way of tenth transistor including a control electrode connected to the control electrode of said fourth transistor, and
said shift register circuit includes a charging circuit for charging a third node, which is a connecting node of said third transistor and said ninth transistor, and a fourth node, which is a connecting node of said fourth transistor and said tenth transistor, when said output terminal is activated.

15. The shift register circuit according to claim 14; wherein
said charging circuit includes,
an eleventh transistor, connected between said output terminal and said third node, diode connected so that a direction from said output terminal to said third node is a charging direction; and
a twelfth transistor, connected between said output terminal and said fourth node, diode connected so that a direction from said output terminal to said fourth node is a charging direction.

16. The shift register circuit according to claim 14, wherein
said charging circuit includes,
a thirteenth transistor, connected between a predetermined power supply terminal and said third node, including a control electrode connected to said output terminal; and
a fourteenth transistor, connected between said power supply terminal and said fourth node, including a control electrode connected to said output terminal.

17. The shift register circuit according to claim 14, wherein
said third node and said fourth node are connected to each other; and
said charging circuit includes a fifteenth transistor, connected between said output terminal and said third node and said fourth node, diode connected so that a direction from said output terminal to said third and said fourth node is a charging direction.

18. The shift register circuit according to claim 14, wherein
said third node and said fourth node are connected to each other; and
said charging circuit includes a sixteenth transistor, connected between a predetermined power supply terminal and said third node and said fourth node, including a control electrode connected to said output terminal.

19. The shift register circuit according to claim 14, further comprising:
a seventeenth transistor for discharging said fourth node based on said first input signal; and
an eighteenth transistor for discharging said third node based on said second input signal.

20. The shift register circuit according to claim 14, further comprising:
a nineteenth transistor for providing said first voltage signal to said fourth node based on said first input signal; and
a twentieth transistor for providing said second voltage signal to said third node based on said second input signal.

21. A shift register circuit comprising a plurality of stages; wherein
each stage is the shift register circuit according to claim 1,
a predetermined first control pulse is input to said first input terminal of leading stage and an output signal of the previous stage is input to said first input terminal of the subsequent stage; and
a predetermined second control pulse is input to said second input terminal of the final stage and an output signal of the next stage is input to said second input terminal of the previous stage.

22. A shift register circuit comprising a plurality of stages including a first dummy stage at the beginning and a second dummy stage at the end; wherein
each stage is the shift register circuit according to claim 1;
a predetermined first control pulse is input to said first input terminal of leading stage excluding said first dummy stage and an output signal of the previous stage is input to said first input terminal of the subsequent stage; and
a predetermined second control pulse is input to said second input terminal of the final stage excluding said second dummy stage and an output signal of the next stage is input to said second input terminal of the previous stage;
said leading stage further includes a twenty-first transistor for discharging said first node of said leading stage based on an output signal of said first dummy stage; and
said final stage further includes a twenty-second transistor for discharging said first node of said final stage based on an output signal of said second dummy stage.

23. The shift register circuit according to claim 22, wherein
said first dummy stage, where said second control pulse is input to said first input terminal, further includes a twenty-third transistor for discharging said first node of said first dummy stage based on said first control pulse; and
said second dummy stage, where said first control pulse is input to said second input terminal, further includes a twenty-fourth transistor for discharging said first node of said second dummy stage based on said second control pulse.

24. An image display apparatus including a shift register circuit of a plurality of stages as a gate line driving circuit; wherein
each stage of said plurality of stages includes,
first and second input terminals, an output terminal and a first clock terminal;
a first transistor for providing a first clock signal input to said first clock terminal to said output terminal;
a second transistor for discharging said output terminal based on a second clock signal having a phase different from said first clock signal;
first and second voltage signal terminals input with first and second voltage signals complementary to each other;
a third transistor for providing said first voltage signal to a first node connected with a control electrode of said first transistor based on a first input signal input to said first input terminal;
a fourth transistor for providing said second voltage signal to said first node based on a second input signal input to said second input terminal; and
a switching circuit for electrically conducting said first node and said output terminal based on said first clock signal when said first node is discharged; wherein
a predetermined first control pulse is input to said first input terminal of leading stage and an output signal of the previous stage is input to said first input terminal of the subsequent stage; and
a predetermined second control pulse is input to said second input terminal of the final stage and an output signal of the next stage is input to said second input terminal of the previous stage.
